(19) United States
(12) Patent Application Publication
(10) Pub. No.: US 2013/0069102 A1
(43) Pub. Date: Mar. 21, 2013

(54) SEMICONDUCTOR LIGHT-EMITTING DEVICE, LIGHT-EMITTING MODULE AND METHOD FOR MANUFACTURING THE SAME

(71) Applicants: Akiya KIMURA, Kanagawa-ken (JP); Kazuhito Higuchi, Kanagawa-ken (JP); Hideo Nishiuchi, Hyogo-ken (JP); Susumu Obata, kanagawa-ken (JP); Toshiya Nakayama, Kanagawa-ken (JP); Yoshiaki Sugizaki, Kanagawa-ken (JP); Akihiro Kojima, Kanagawa-ken (JP); Yosuke Akimoto, Kanagawa-ken (JP)

(72) Inventors: Akiya KIMURA, Kanagawa-ken (JP); Kazuhito Higuchi, Kanagawa-ken (JP); Hideo Nishiuchi, Hyogo-ken (JP); Susumu Obata, kanagawa-ken (JP); Toshiya Nakayama, Kanagawa-ken (JP); Yoshiaki Sugizaki, Kanagawa-ken (JP); Akihiro Kojima, Kanagawa-ken (JP); Yosuke Akimoto, Kanagawa-ken (JP)

(73) Assignee: KABUSHIKI KAISHA TOSHIBA, Tokyo (JP)

(21) Appl. No.: 13/607,418

(22) Filed: Sep. 7, 2012

(30) Foreign Application Priority Data
Sep. 21, 2011 (JP) 2011-206632

(51) Int. Cl. H01L 33/36

(52) U.S. Cl. 257/99; 438/22; 257/E33.062

(57) ABSTRACT

A semiconductor light-emitting device includes a laminated body that is configured to emit light from a main surface thereof, first and second electrodes, each disposed on a surface of the laminated body that is opposite the main surface, a first terminal that is electrically coupled to the first electrode, has a concave edge but not a convex edge, and has at most three exposed sides, and a second terminal that is electrically coupled to the second electrode, has a concave edge but not a convex edge, and has at most three exposed sides.

### CROSS-REFERENCE TO RELATED APPLICATION

This application is based upon and claims the benefit of priority from Japanese Patent Application No. 2011-206632, filed Sep. 21, 2011; the entire contents of which are incorporated herein by reference.

### FIELD

Embodiments described herein relate generally to a semiconductor light-emitting device, a light-emitting module and a method for manufacturing the same.

### BACKGROUND

Semiconductor light-emitting devices that emit white light and visible light have been used as light sources in lighting equipment and display devices.

Among the various kinds of semiconductor light-emitting devices, one type has a semiconductor light-emitting device mounted on one side of a substrate and having a light-emitting surface oriented perpendicular to the mounting surface of the substrate; this emitting side is called a side view type.

In semiconductor light-emitting devices of the side view type, terminal surfaces for soldering the light-emitting device to the substrate may be formed on the side of the semiconductor light-emitting device that faces the substrate. Because of that, the soldering surfaces are hidden, which is undesirable.

Consequently, a semiconductor light-emitting device with an exposed terminal surface on a side of the device has been proposed.

However, if the terminal surface is simply exposed on the sides, new problems will arise; for example, the outer shape becomes complicated, and this complicates manufacturability and/or increases external dimensions of the light-emitting device.

### DESCRIPTION OF THE DRAWINGS

FIGS. 1A to 1D are schematic diagrams that illustrate a semiconductor light-emitting device according to a first embodiment.

FIG. 2A to 2C are schematic diagrams that illustrate a light-emitting module of the first embodiment.

FIGS. 3A and 3B are schematic perspective views that illustrate the manufacturing method of the semiconductor light-emitting device of the first embodiment.

FIGS. 4A and 4B are schematic sectional views that illustrate the manufacturing method of the semiconductor light-emitting device of the first embodiment.

FIGS. 5A and 5B are schematic sectional views that illustrate the manufacturing method of the semiconductor light-emitting device of the first embodiment.

FIGS. 6A and 6B are schematic sectional views that illustrate the manufacturing method of the semiconductor light-emitting device of the first embodiment.

FIGS. 7A to 7C are schematic sectional views that illustrate the manufacturing method of the semiconductor light-emitting device of the first embodiment.

FIGS. 8A and 8B are schematic sectional views that illustrate the manufacturing method of the semiconductor light-emitting device of the first embodiment.

FIGS. 9A and 9B are schematic sectional views that illustrate the manufacturing method of the semiconductor light-emitting device of the first embodiment.

FIGS. 10A and 10B are schematic sectional views that illustrate the manufacturing method of the semiconductor light-emitting device of the first embodiment.

FIGS. 11A and 11B are schematic sectional views that illustrate the manufacturing method of the semiconductor light-emitting device of the first embodiment.

FIGS. 12A and 12B are schematic sectional views that illustrate the manufacturing method of the semiconductor light-emitting device of the first embodiment.

FIGS. 13A and 138 are schematic sectional views that illustrate the manufacturing method of the semiconductor light-emitting device of the first embodiment.

FIG. 14 is a schematic sectional view that illustrates the manufacturing method of the semiconductor light-emitting device of the first embodiment.

FIGS. 15A and 15B are schematic sectional views that illustrate the manufacturing method of the semiconductor light-emitting device of the first embodiment.

FIGS. 16A and 16B are schematic sectional views that illustrate the manufacturing method of the light-emitting module of the first embodiment.

FIGS. 17A and 17B are schematic sectional views that illustrate the manufacturing method of the light-emitting module of the first embodiment.

FIGS. 18A and 188 are schematic sectional views that illustrate the manufacturing method of the light-emitting module of the first embodiment.

FIGS. 19A and 198 are schematic sectional views that illustrate the manufacturing method of the light-emitting module of the first embodiment.

FIGS. 20A to 20D are schematic diagrams that illustrate a semiconductor light-emitting device according to a second embodiment.

FIGS. 21A to 21C are schematic diagrams that illustrate a light-emitting module of the second embodiment.

FIGS. 22A to 22D are schematic diagrams that illustrate a semiconductor light-emitting device according to a third embodiment.

FIGS. 23A to 23C are schematic diagrams that illustrate a light-emitting module of the third embodiment.

### DETAILED DESCRIPTION

In general, we will describe embodiments by referring to the drawings. In addition, in each drawing, we give an advanced but concise explanation by using the same reference numbers for similar elements.

According to some embodiments, there is provided a semiconductor light-emitting device and light-emitting module that enable reduction of size and improved manufacturability and a method for manufacturing the semiconductor light-emitting device.

The semiconductor light-emitting device according to one embodiment includes a laminated body that is configured to emit light from a main surface thereof, first and second electrodes, each disposed on a surface of the laminated body that is opposite the main surface, a first terminal that is electrically coupled to the first electrode, has a concave edge but not a convex edge, and has at most three exposed sides, and a second terminal that is electrically coupled to the second electrode, has a concave edge but not a convex edge, and has at most three exposed sides.

### Embodiment 1

### The Semiconductor Light-Emitting Device)

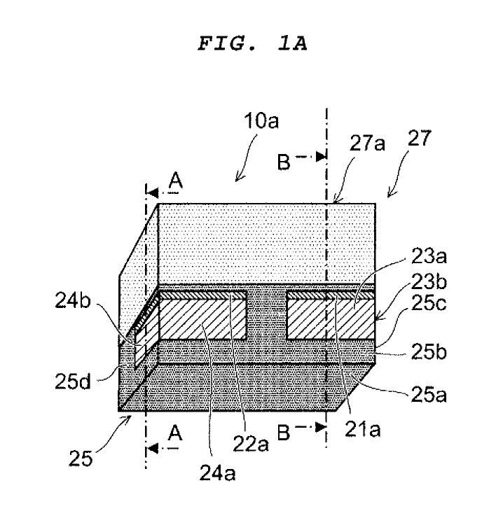

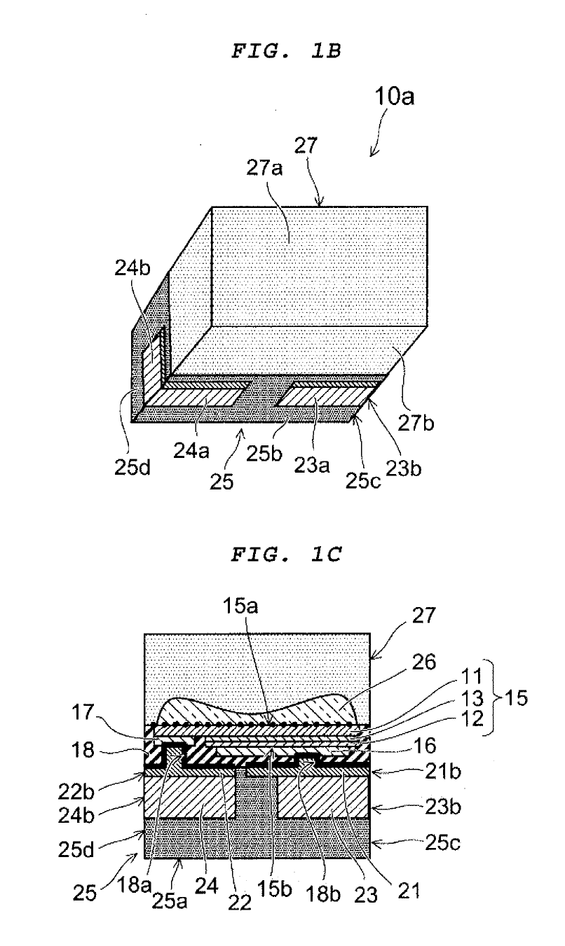

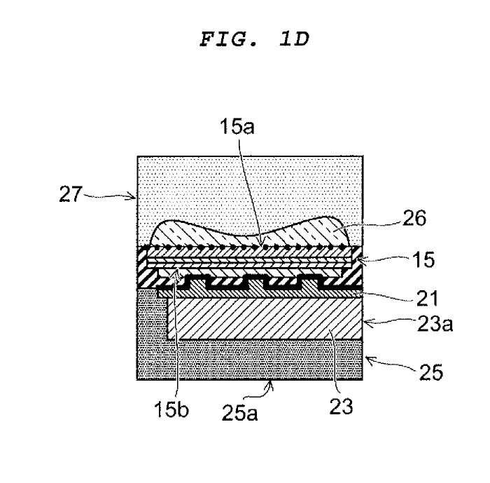

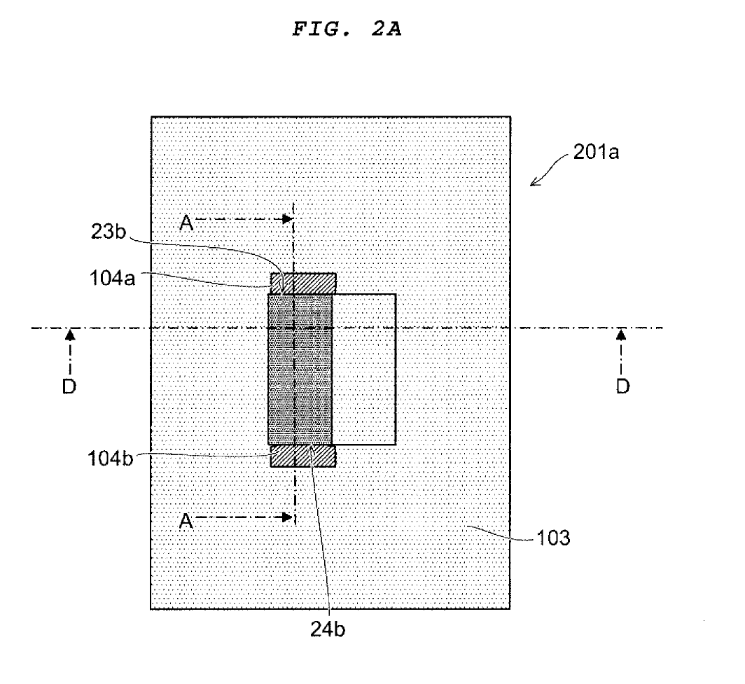

FIGS. 1A to 1D are schematic diagrams that illustrate a semiconductor light-emitting device according to a first embodiment.

FIGS. 1A and 1B are perspective views that schematically show a semiconductor light-emitting device 10a of the first embodiment, specifically: FIG. 1C is an A-A sectional view of FIG. 1A; and FIG. 1D is the B-B sectional view of FIG. 1A.

As shown in FIGS. 1A and 1B, the semiconductor light-emitting device 10a includes a sealing part 25 (whose external form in combination with terminal surfaces 23a, 23b, 24a, and 24b is in the shape of a rectangular prism with flat exterior surfaces) and a light-transmitting part 27. As used herein, the term “prism” is defined as a geometric solid with cross-sections that are parallel to the base of the solid. Thus, because the semiconductor light-emitting device 10a is configured as a rectangular prism, the semiconductor light-emitting device 10a includes concave edges but no convex edges, i.e., every internal angle of the geometric solid is less than or equal to 180 degrees.

As shown in FIGS. 1C and 1D, the semiconductor light-emitting device 10a has a laminated body 15, which includes a p-type gallium nitride (GaN) layer 12 (which represents an example of the first semiconductor layer of the first conductivity type) and an n-type GaN layer 11 (which represents an example of the second semiconductor layer of the second conductivity type), and the light-emitting layer 13. The light-emitting layer 13 is disposed between p-type GaN layer 12 and n-type GaN layer 11. The laminated body 15 includes the first main surface 15a on the side of n-type GaN 11 and the second main side 15b on the other side. The laminated body 15 emits the light emitted by the light-emitting layer 13 from the first main surface 15a.

The light emitted from laminated body 15 is emitted through the exterior of the emitting surface 27a after being transmitted through the light-transmitting part 27. The light-emitting surface 27a of light-transmitting part 27 is substantially parallel to the first main surface 15a of laminated body 15.

In addition, lens 26 can be formed between laminated body 15 and light-transmitting part 27. Lens 26 improves the directivity by concentrating the light emitted by laminated body 15.

On the other hand, p-side electrode 16 (which represents an example of the first electrode), which is electrically connected to p-type GaN layer 12, and n-side electrode 17 (which represents an example of the second electrode) are formed on the second main side 15b of laminated body 15. N-side electrode 17 is formed on the surface of n-type GaN layer 11 by selectively etching p-type GaN layer 12 and light-emitting layer 13.

In addition, insulation 18, which covers laminated body 15, p-side electrode 16, and n-side electrode 17 is formed. Insulation 18 comes from, for example, polyimide. Then, p-side re-wiring part or interconnect 21 and n-side re-wiring part or interconnect 22 are formed electrically connected to p-side electrode 16 and n-side electrode 17, respectively, through contact holes 18b and 18a, respectively, which are formed in insulation 18.

On a surface of p-side interconnect 21, p-side wiring part or terminal 23 (which represents an example of the first wiring part or terminal) is disposed on a surface of p-side interconnect 21. P-side terminal 23 is electrically connected to p-side electrode 16 through p-side interconnect 21. Similarly, on a surface of n-side interconnect 22, n-side wiring part or terminal 24 (which represents an example of the second wiring part or terminal) is formed. N-side terminal 24 is electrically connected to n-side electrode 17 through n-side interconnect 22.

P-side terminal 23 extends in a direction parallel to the second main side 15b of laminated body 15, as shown in FIG. 1C. P-side terminal 23 has an exposed surface, referred to herein as terminal surface 23a, that is parallel to and contiguous with side 25b (which represents an example of the first side). As shown in FIG. 1A, side 25b intersects substantially side 25a of sealing part 25 in one direction and side 25c (which represents an example of the second side) in an orthogonal direction. More precisely, terminal surface 23a (which represents an example of the first terminal surface) of p-side terminal 23 is exposed on side 25b of sealing part 25.

Terminal surface 23b (which represents an example of the second terminal surface), is contiguous with (i.e., shares an edge with) terminal surface 23a, and is exposed on side 25c, which is contiguous with (i.e., shares an edge with) side 25b. More precisely, terminal surfaces 23a and 23b are contiguous with each other along a shared edge as shown in FIGS. 1A and 1B.

Terminal surface 23a is formed as a surface that is substantially flush with side 25b of sealing part 25 and therefore does not significantly project from side 25b of sealing part 25. Terminal surface 23b is formed as a surface that is substantially flush with side 25c of sealing part 25 and therefore does not significantly project from side 25c of sealing part 25.

Similarly, n-side terminal 24 is exposed and flush with side 25b and side 25d (which represents an example of the third side). Side 25d extends in a parallel direction to the second main side 15b of laminated body 15 and substantially intersects side 25a of sealing part 25 along an edge as shown in FIG. 1A. More precisely, terminal surface 24a (which represents the third terminal surface) of n-side terminal 24 is exposed on side 25b of sealing part 25.

Terminal surface 24b (which represents an example of the fourth surface) is contiguous with (i.e., shares an edge with) terminal surface 24a, and is exposed on side 25d, which is contiguous with (i.e., shares an edge with) side 25b. More precisely, terminal surfaces 24a and 24b are contiguous surfaces that intersect at a shared edge.

Terminal surface 24a is formed as a surface that is substantially flush with side 25b of sealing part 25 and therefore does not project from side 25b of sealing part 25.

Terminal surfaces 23a, 23b, 24a, and 24b are electrically connected through electrodes and connecting materials formed, for example, by the substrate.

Because terminal surfaces 23a, 23b, 24a, and 24b do not project from the sides surfaces of the semiconductor light-emitting device 10a, the outer sides of semiconductor light-emitting device 10a can be configured as flat surfaces. To do so, a plurality of semiconductor light-emitting devices 10a are formed simultaneously in a batch, to facilitate subsequent separation thereof into individual devices. Embodiments of the invention also enable reduction in waste when separating these semiconductor light-emitting devices into individual devices.

Also, as it is possible to make semiconductor light-emitting device 10a of roughly the same size as the laminated body 15 that is a light source; it is also possible to miniaturize the semiconductor light-emitting device 10a.

Please note that the details of forming many semiconductor light-emitting devices 10a in a lump and separating them in individual pieces are explained later.

In addition, if terminal surfaces 23a, 23b, 24a, and 24b don't protrude from the sides, the movement of connecting materials on the sides of the semiconductor light-emitting device 10a is not inhibited when the semiconductor light-emitting device 10a is being coupled to the substrate 100. As a result, good fillets can be formed.

Note that the details of connecting the semiconductor light-emitting device 10a to the substrate are also explained later.

To form p-side interconnect 21, n-side interconnect 22, p-side terminal 23, and n-side terminal 24, materials such as copper, gold, nickel, and silver can be used. Among these materials, copper provides good thermal conductivity, high migration resistance, and excellent adhesion with insulating materials.

Sealing part 25 has a quadrangular prism shape. It is formed in order to cover p-side terminal 23 and n-side terminal 24. Sealing part 25 can be formed on an insulating material. Epoxy resin, silicone resin, and fluorine resin, for example, can be given as examples of sealing part 25 materials.

### (Light-Emitting Module)

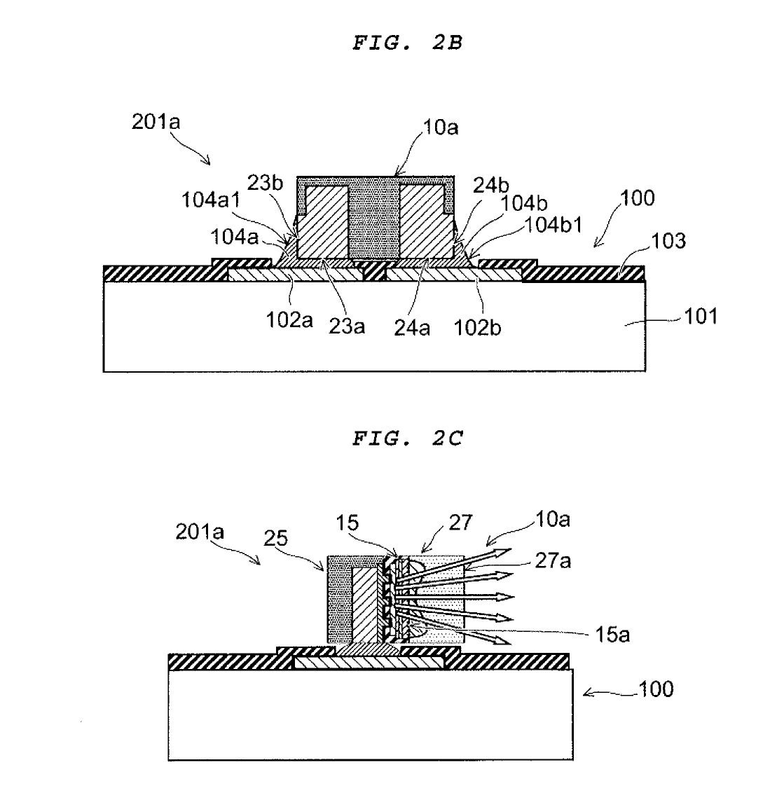

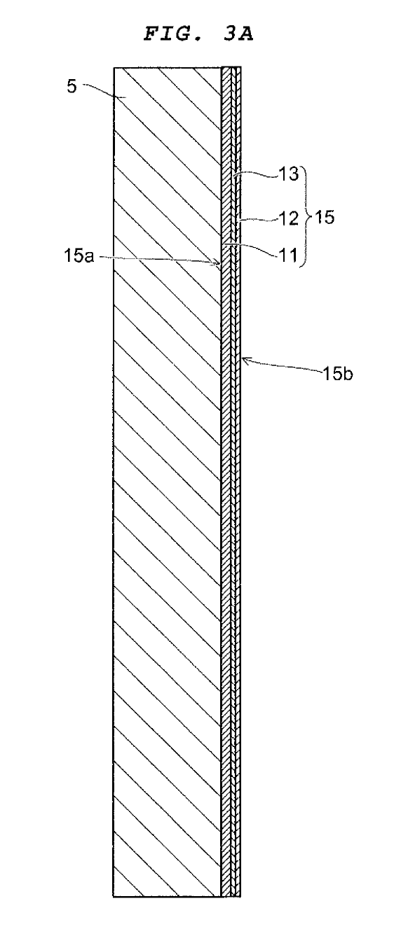

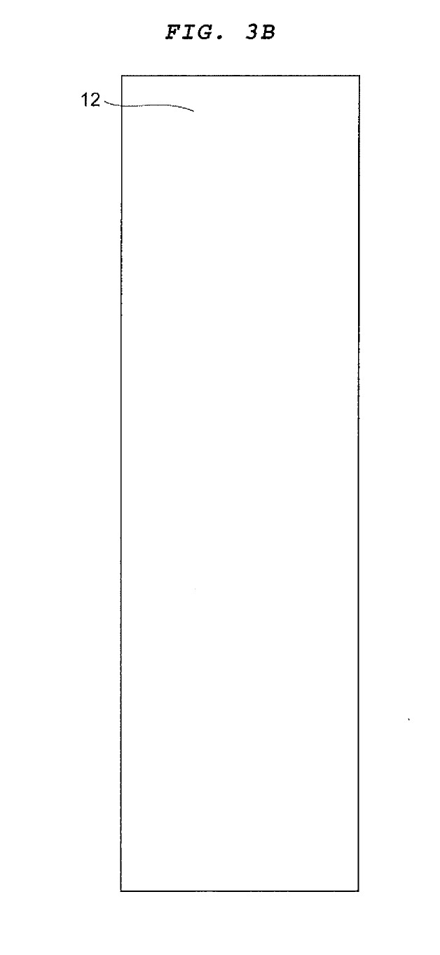

FIGS. 2A to 2C are schematic diagrams that illustrate the light-emitting module 201a in the semiconductor light-emitting device 10a. FIG. 2A is a schematic plain view of the light-emitting module 201a; FIG. 2B is an A-A sectional view of FIG. 2A; and FIG. 2C is a sectional view D-D of FIG. 2A.

As shown in FIGS. 2A to 2C, on the light-emitting module 201a, the semiconductor light-emitting device 10a and the substrate 100 are provided.

Electrode 102a (which represents an example of the third electrode) and electrode 102b (which represents an example of the fourth electrode) are formed on the surfaces of base 101 of substrate 100. On the base 101 and on electrode 102a and 102b, insulating part 103, which is patterned, is provided, and the parts electrically connected to the semiconductor light-emitting device 10a are exposed. Also, wiring patterns formed on electrode 102a or 102b can be appropriately established.

In a plan view, the bigger the area of electrode 102a and 102b, the better the light-emitting module 201a functions. If we enlarge the area of electrodes 102a and 102b, it is possible to encourage the spread of heat; therefore, it is possible to improve the heat dissipation.

Insulating part 103 can be formed by white materials such as white epoxy resin. If insulating part 103 is white, any light emitted by light-emitting layer 13 that propagates in the direction of insulating part 103 can be reflected; therefore, it is possible to reduce the loss of light.

The semiconductor light-emitting device 10a is disposed on the substrate 100. Side 25b of sealing part 25 of the semiconductor light-emitting device 10a and side 27b of light-transmitting part 27 are facing the substrate 100.

Because of that, the first main surface 15a of laminated body 15 and the light-emitting surface 27a of the light-transmitting part 27 are oriented substantially perpendicular to the substrate 100. As a result, as shown in FIG. 2C, the light is emitted by laminated body 15 in a direction parallel to the substrate 100. The semiconductor light-emitting device 10a that emits the light in this way is called a side-view type. More precisely, the light-emitting module 201a includes a side-view type semiconductor light-emitting device 10a. The light-emitting module 201a, which includes the side-view type semiconductor light-emitting device is suitable for purposes such as radiating the light from the side surface of the light-guiding plate (for example, for the backlight of a liquid crystal display). As previously described, if the semiconductor light-emitting device 10a is roughly the same size as the light source, such as laminated body 15, it is possible to miniaturize the light-emitting module 201a and/or to miniaturize products that include the light-emitting module, such as a liquid crystal display.

Next, we illustrate the semiconductor light-emitting device 10a and its connection to the substrate 100.

As shown in FIG. 2B, the semiconductor light-emitting device 10a and the substrate 100 are electrically connected through connecting materials 104a and 104b.

In the embodiment illustrated in FIG. 2B, terminal surfaces 23a and 23b are electrically connected to electrode 102a through connecting material 104a.

Similarly, in this embodiment, terminal surfaces 24a and 24b are electrically connected to electrode 102b through connecting material 104b.

Connecting materials 104a and 104b can be, for example, solder or conductive paste.

Here, terminal surfaces 23a and 24a are provided from the center of the semiconductor light-emitting device 10a to its shifted position. Because of this, if we try to make any connection that depends only on the terminal surfaces 23a and 24a, if the supply of connecting materials 104a and 104b is badly balanced and causes the semiconductor light-emitting device 10a to lean, the direction of light emission might be deviated.

Also, if we try to make any connection that depends only on the terminal surfaces 23a and 24a, because of the small connection area, the connection might not be strong enough. To prevent this, terminal surfaces 23b and 24b are also used when connecting to the semiconductor light-emitting device 10a to the substrate 100.

When connecting the semiconductor light-emitting device 10a to the substrate 100, connecting material 104a is applied not only to terminal surface 23a but to terminal surface 23b, so that an electrical connection is established on terminal surface 23b. And, connecting material 104a is applied not only to terminal surface 24a but also to terminal surface 24b, so that an electrical connection is established on terminal surface 24b.

As previously described, if terminal surfaces 23b and 24b don't protrude from side surfaces, the application of connecting materials 104a and 104b to terminal surfaces 23b and 24b is not inhibited. As a result, good fillets 104a1 and 104b1 can be formed. Thus, the reliability and strength of the connection between the semiconductor light-emitting device 10a and the substrate 100 is improved.

In addition, because it is possible to visually inspect the state of connecting materials 104a or 104b on terminal surfaces 23b and 24b and the state of fillets 104a1 and 104b1 on terminal surfaces 23b and 24b, it is easy to confirm the quality of connection between the semiconductor light-emitting device 10a and the substrate 100. As a result, it is possible to facilitate the inspection or to improve the accuracy of the inspection.

Also, when connecting the semiconductor light-emitting device 10a to the substrate 100, there are cases where the so-called die-bonding method can be used. When using the die-bonding method, connecting materials 104a and 104b situated between the semiconductor light-emitting device 10a and the substrate 100 are compressed. In this case, the stress occurring on connecting materials 104a and 104b can be absorbed by p-side terminal 23, n-side terminal 24, and sealing part 25 formed by the semiconductor light-emitting device 10a. As a result, even in the cases where die-bonding method is used, it is possible to relax the stress on laminated body 15. As a result, reliability and light output of semiconductor light-emitting device 10a can be increased.

### (The Manufacturing Method of the Semiconductor Light-Emitting Device)

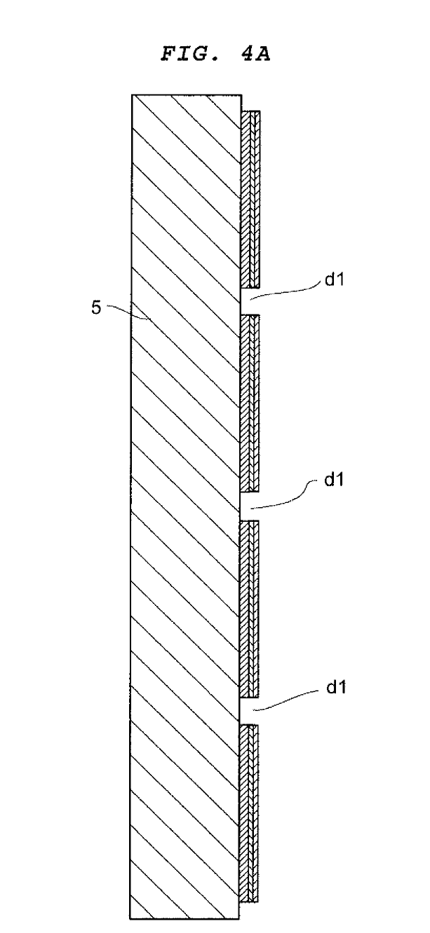

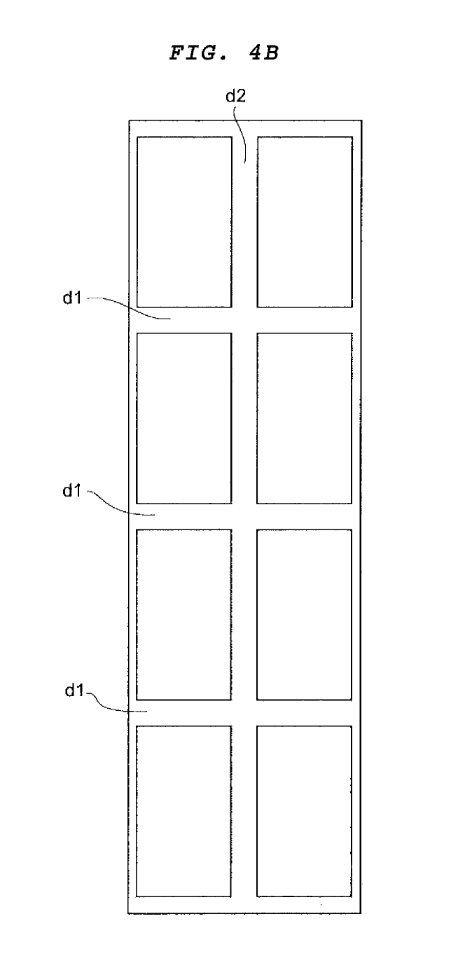

FIGS. 3A to 15B are schematic sectional views that illustrate the manufacturing method of the semiconductor light-emitting device 10a.

According to the manufacturing method of the semiconductor light-emitting device 10a, it is possible, for example, to form a plurality of semiconductor light-emitting devices 10a in a batch on the top of the substrate 5. Therefore, in order to explain FIGS. 3A to 15B, we will illustrate the forming of the semiconductor light-emitting device 10a on a region of the substrate 5.

FIG. 3A shows a cross-sectional view of laminated body 15 formed on the main surface of the substrate 5, including n-type GaN layer 11, light-emitting layer 13, and p-type GaN layer 12. FIG. 3B is a plan view of FIG. 3A.

On the main surface of the substrate 5, n-type GaN layer 11 is formed, and on that part, light-emitting layer 13 and n-type GaN layer 12 are formed. On the substrate 5, it is possible to use, for example, sapphire substrate and the MOCVD (metal organic chemical vapor deposition) method on the main surface in order to sequentially grow n-type GaN layer 11, which is a GaN Nitride semiconductor layer system, light-emitting layer 13, and n-type GaN layer 12.

In this case, between n-type GaN layer 11 and substrate 5, a buffer layer (not shown), for example, can be formed. N-type GaN layer 11 includes, for example, silicon (Si) as n-type impurities. P-type GaN layer 12 includes, for example, magnesium (Mg) as p-type impurities. Light-emitting layer 13 includes a quantum well structure that includes GaN and indium gallium nitride (InGaN) and emits blue, purple, or blue-violet light, for example. Also, ultraviolet radiation can be emitted by using aluminum gallium nitride (AlGaN) as the material.

The first main surface 15a of laminated body 15 is the surface that is connected to the substrate 5 on n-type GaN layer 11. Then, the surface of p-type GaN layer 12 is the second main surface 15b of laminated body 15.

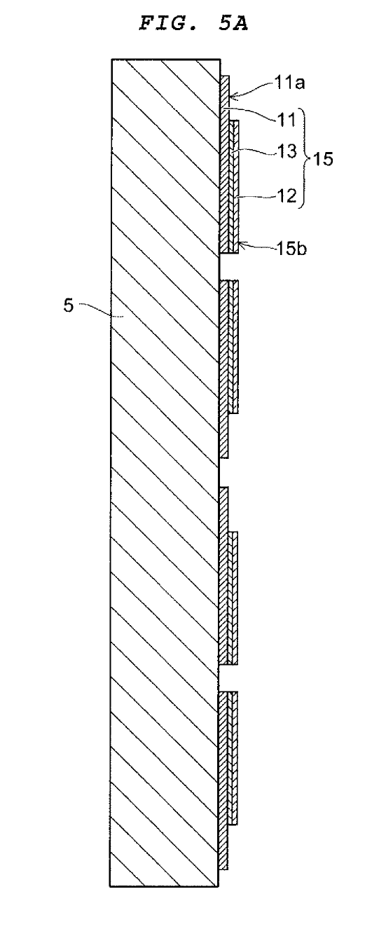

FIG. 4A and the plan view thereof. FIG. 4B, illustrate how a groove is formed to reach the substrate 5 by penetrating laminated body 15 in dicing regions d1 and d2. For example, by forming a resist mask (not shown) on the surface of laminated body 15, the groove is formed by using the RIE (reactive-ion etching) technique. Dicing regions d1 and d2 are formed on top of the substrate 5 of the wafer state; for example, on the lattice. In the groove formed by dicing regions d1 and d2, laminated body 15 is separated into individual units that are each inside a semiconductor light-emitting device 10a. In addition, the process of separating laminated body 15 happens after the selective etching of p-type GaN layer 12 or later, after forming p-side electrode 16 or n-side electrode 17 into individual units.

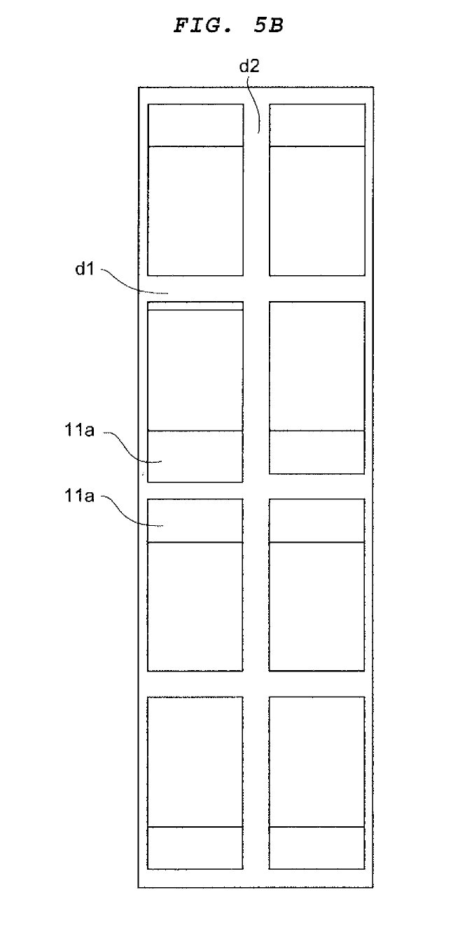

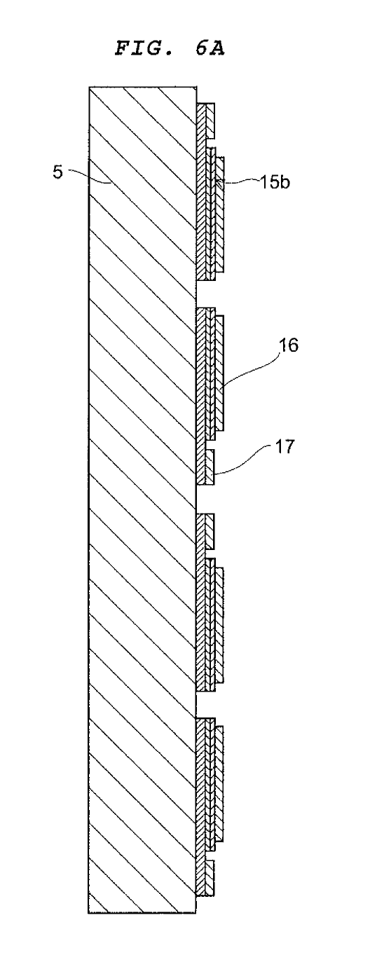

The next step, as shown in FIG. 5A and the plan view thereof, FIG. 5B, is to selectively remove a part of p-type GaN layer 12 and light-emitting layer 13 in order to expose a part of n-type GaN layer 11 on the second main surface 15b. For example, by forming a resist mask (not shown) on the surface of laminated body 15 and by using the RIE technique and the etching, a part of n-type GaN layer 11 is exposed on the second main surface 15b.

As shown in FIG. 5B, the exposed surface 11a of n-type GaN layer 11 is formed alternately reversed so that the exposed surface 11a of one individual unit that will become a semiconductor light-emitting device 10a is adjacent to the exposed surface 11a of an adjacent individual unit that will become a semiconductor light-emitting device 10a, where the adjacent exposed surfaces 11a are separated by a dicing region d1. The position of the exposed surface of n-type GaN layer 11 is not limited to this example; it can also be in the same direction along dicing region d2.

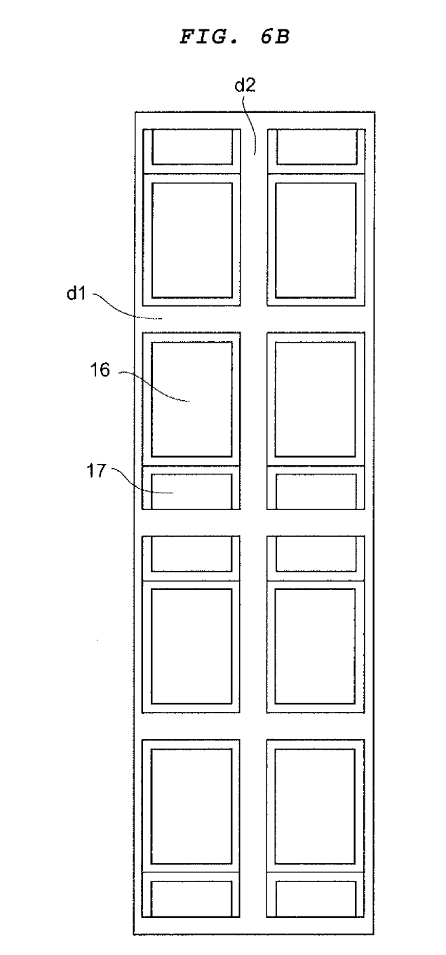

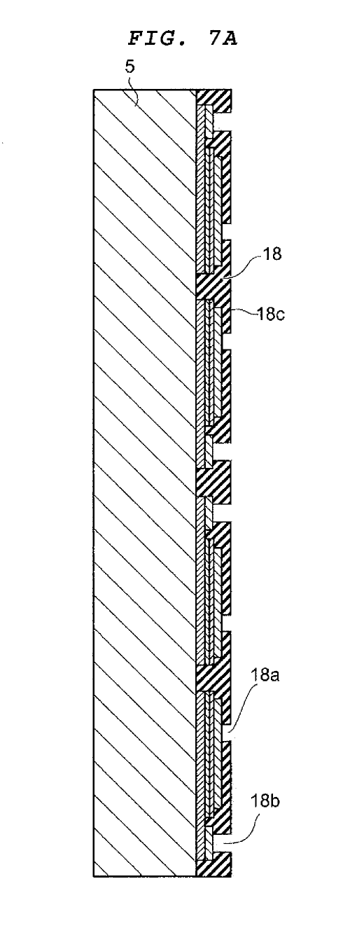

Now, as shown in FIG. 6A and the plan view thereof, FIG. 6B, on the second main surface 15b, p-side electrode 16 and n-side electrode 17 are formed. As shown in FIG. 6B, in the direction along dicing region d2, p-side electrode 16 and n-side electrode 17 are formed alternately reversed. P-side electrode 16 is formed on the surface of p-type GaN layer 12. On n-side electrode 17, for example, an exposed surface 11a of n-type GaN layer 11 is formed by using a laminated film of titanium (Ti) or aluminum (Al).

P-side electrode 16 and n-side electrode 17 are formed, for example, by sputtering or the vapor deposition method. There is no forming order between p-side electrode 16 and n-side electrode 17. They can also be formed at the same time with the same materials.

It is preferable that p-side electrode 16 is configured to reflect the light emitted from light-emitting layer 13. P-side electrode 16 includes, for example, silver, silver alloy, aluminum, aluminum alloys, etc.; also, p-side electrode 16 can be configured with a metal top coat, which inhibits sulfide or oxidation.

In addition, a passivation film can be formed between p-side electrode 16 and n-side electrode 17 and on the edge of light-emitting layer 13 (side surface) (not shown). A passivation film is formed, for example, from silicon nitride film or silicon oxide film by using the CVD (chemical vapor deposition) technique. To form ohmic contact between p-side electrode 16, n-side electrode 17, and laminated body 15, activation annealing can be carried out if necessary.

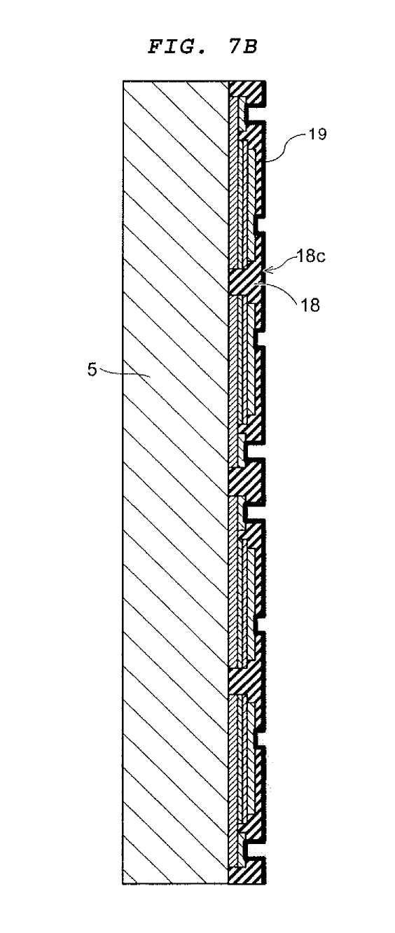

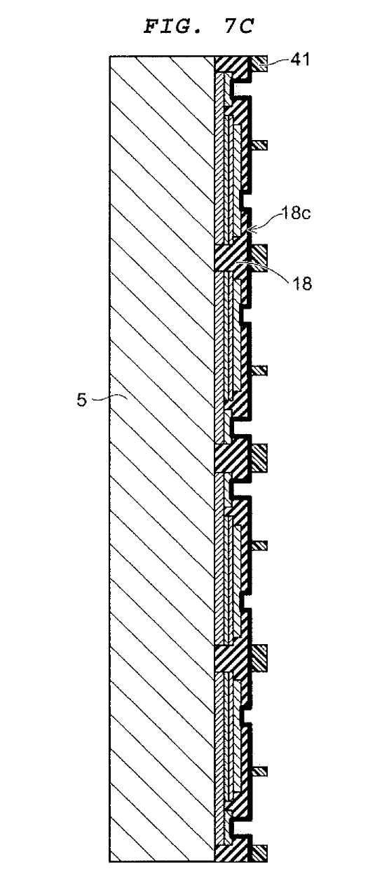

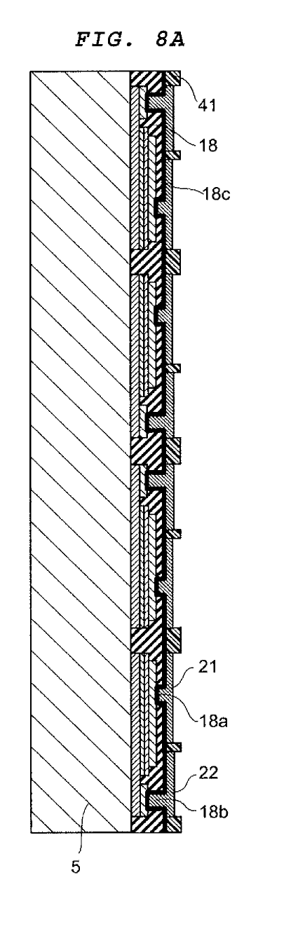

As shown in FIG. 7A, once the entire exposed parts on the main surface of the substrate 5 are covered by insulation 18, contact holes 18a and 18b are formed. Contact holes 18a and 18b are formed, for example, by using the wet-etching technique to selectively remove insulation 18. Contact hole 18a reaches p-side electrode 16, while contact hole 18b reaches n-side electrode 17.

In order to form insulation 18, photosensitive polyimide, benzocyclobutene (benzocyclo butene), and other organic materials can be used. In this case, by using the photolithography technique to directly expose and develop insulation 18, contact holes 18a and 18b can be formed. Or, inorganic film such as silicon nitride film or silicon oxide film can also be used in order to form insulation 18. Contact holes 18a and 18b can also be formed by using the etching and resist mask technique when inorganic films are used.

The next step, as shown in FIG. 7B, is to form metal seed 19 on the wiring surface 18c. Thus, one surface of insulation 18 contacts laminated body 17 and metal seed 19 is formed on an opposite surface of insulation 18. Metal seed 19 is also formed at the bottom and the inner wall of contact holes 18a and 18b.

Metal seed 19 can be formed, for example, by using the sputtering technique. Metal seed 19 can include multi-layer films such as titanium (Ti) or topper (Cu), which are formed one by one on insulation 18.

The next step, as shown in FIG. 7C, is to form a resist mask 41 on the top of metal seed 19. After that, a Cu film is formed by electrolytic cu plating. Plating current flows through metal seed 19, and the Cu film is formed on the surface of metal seed 19.

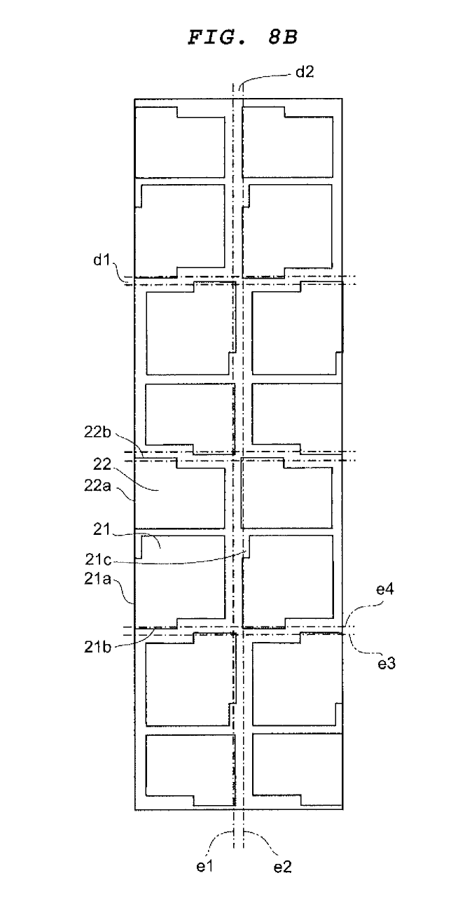

According to this, as shown in FIG. 8A and the plan view thereof, FIG. 8B, p-side interconnect 21 and n-side interconnect 22 are selectively formed on the top of wiring surface 18c of insulation 18. P-side interconnect 21 and n-side interconnect 22 are formed by the Cu film formed at the same time as the Cu film from the plating. P-side interconnect 21 is also formed inside contact hole 18a and is electrically connected to p-side electrode 16 through metal seed 19. N-side interconnect 22 is also formed inside contact hole 18b and is electrically connected to n-side electrode 17 through metal seed 19.

Here, dicing region d1 extends along the direction (FIG. 8B in horizontal direction) of side surface 22b of n-side interconnect 22 and side surface 21 b of p-side interconnect 21. Then, according to FIGS. 1A and 1B, side surface 21b of p-side interconnect 21 is exposed on side surface 25c of sealing part 25 and side surface 22b of n-side interconnect 22 is exposed on side surface 25d.

Dicing region d2 extends along the direction of side surface 22a of n-side interconnect 22 and side surface 21a of p-side interconnect 21 (i.e., along the vertical direction in FIG. 8B). Then, according to FIGS. 1A and 1B, side surface 22a of n-side interconnect 22 and side surface 21a of p-side interconnect 21 are exposed on side surface 25b of sealing part 25.

FIG. 8B, showing the edges e1, e2, e3, e4 by a dashed line, represents the boundaries that are cut during the dicing process. Then, side surfaces 21a and 22a in FIG. 8B are formed to extend beyond the edges e1 and e2 in order to jut into dicing region d2. Side surfaces 21b and 22b are formed to extend beyond the edges e3 and e4 in order to jut into dicing region d1.

In addition, on the facing side between n-side interconnect 22 and p-side interconnect 21, notched part 21c is formed on the corner of the side surface 21a. The notched part 21c is provided between side surfaces 21a and 22a. As a result, it is possible to enlarge the space between side surfaces 21a and 22a, which are exposed from the sealing part 25 after the dicing. This helps, when connecting to the substrate, to avoid a short-circuit due to solder or something similar.

On the other hand, except for the notched part 21c, the space between p-side interconnect 21 and n-side interconnect 22 can be minimized to the limit of the manufacturing process. More precisely, the area of p-side interconnect 21 can be enlarged without being subjected to constraints of the space on terminal surfaces 23a and 24a exposed on side surface 25b of sealing part 25. As a result, it is possible to improve heat dissipation by expanding the contact area between p-side interconnect 21 and p-side electrode 16 in order to reduce current density. For example, it is possible to connect, between p-side interconnect 21 and p-side electrode 16 through many contact holes 18a.

In the manufacturing method of this embodiment, as shown in FIG. 83, side surface 21a and side surface 22a don't exist disproportionately on either side of dicing region d2; they are alternately provided on both sides in the width direction of dicing region d2. Similarly, side surface 21b and side surface 22b don't exist disproportionately on either side of dicing region d1; they are alternately provided on both sides in the width direction of dicing region d1. As a result, when cutting dicing region d2 by using a dicing blade, it is possible to evenly cut side surface 21a and side surface 22a, which are metal, with both sides of the dicing blade. As a result, it is possible to equalize the load on the edges of dicing blade. More precisely, it is possible to extend product life span by avoiding clogging or breakdown of the dicing blade.

In addition, in the example used to explain FIG. 8B, side surfaces 21a and 22a of edge e1 and side surfaces 21a and 22a of edge e2 are alternately positioned extending along the direction of dicing region d2. However, other arrangements of side surfaces 21a and 22a with respect to edges e1 and e1 also fall within the scope of the invention. Generally, in some embodiments, side surfaces 21a and 22a are arranged in an acceptable fashion as long as there is no bias on either side of edge e1 or edge e2.

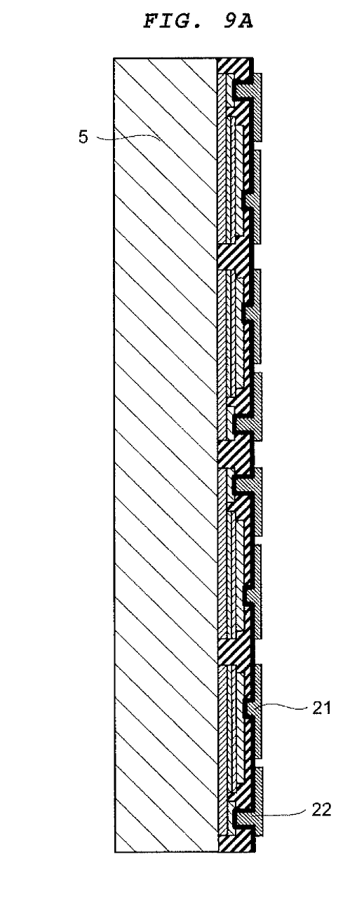

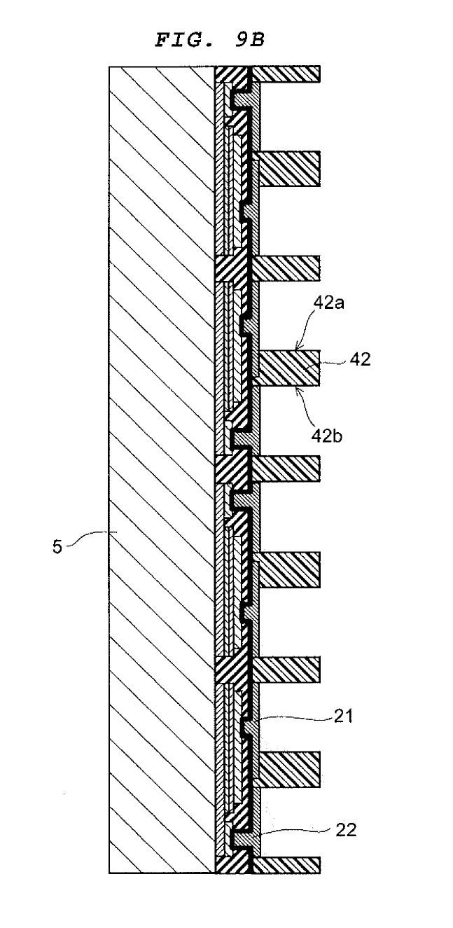

FIG. 9A is a sectional view showing the conditions after resist mask 41, which is used to form p-side interconnect 21, and n-side interconnect 22 are removed. Resist mast 41, for example, can be removed using the wet ashing technique, which uses organic solvent, or the dry ashing technique, which uses oxygen plasma.

The next step, as shown in FIG. 9B, is to form resist mask 42 in order to form a terminal. Resist mask 42 is formed to be thicker than the previously described resist mask 41. In addition, it is possible to leave resist mask 41 without removing it and to subsequently form resist mask 42 on the top of resist mark 41.

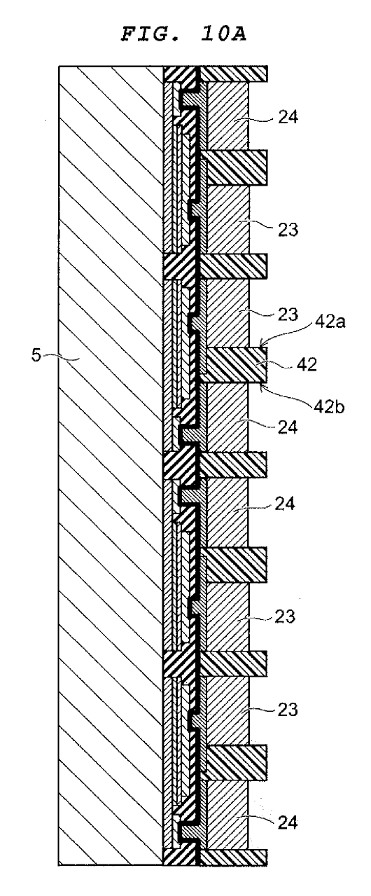

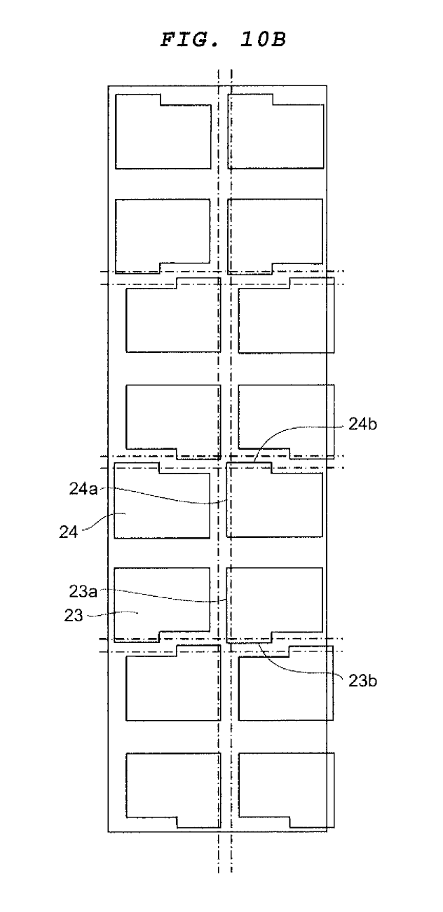

Then, as shown in FIG. 10A and the plan view thereof, FIG. 10B, p side wiring-part 23 and n-side terminal 24 are formed. For example, resist mask 42 is used to selectively carry out Cu electrolytic plating. And also in this case, Cu film is formed on the top of p-side interconnect 21 and n-side interconnect 22 by letting current flow through metal seed 19.

More precisely, p-side terminal 23 is inside opening side 42a formed on resist mask 42; it is formed on the surface of p-side interconnect 21. N-side terminal 24 is inside opening side 42b formed by resist mask 42; it is formed on the surface of n-side interconnect 22. P-side terminal 23 and n-side terminal 24 are formed at the same time as Cu electrolytic plating and have become copper material.

Then, terminal surface 23a, which is the edge of p-side terminal 23 is exposed on side surface 25b of sealing part 25 after dicing. Similarly, n-side terminal 24, is exposed on side surface 25b of sealing part 25 after dicing, in order to form terminal surface 24a; p-side terminal 23 and n-side terminal 24 are formed to extend into dicing region d2, i.e., over the edges e1 and e2 of the dicing region d2. Also, as the edge of p-side terminal 23, terminal surface 23b is exposed on side surface 25c of sealing part 25 after dicing. Similarly, as the edge of n-side terminal 24, terminal surface 24b is exposed on side surface 15d. In order to form terminal part 24b, p-side terminal 23 and n-side terminal 24 are formed to extend into the dicing region d1 over the edges e3 and e4 of the dicing region d1.

As shown in FIG. 10B, p-side terminal 23 and n-side terminal 24 are positioned with no bias on either side of dicing region d2, and are provided evenly on both sides in the direction in which dicing region d2 extends. Then, in the case where dicing region d2 is cut by a dicing blade, p-side terminal 23 and n-side terminal 24, which are metal, are evenly cut by both edges of the dicing blade. As a result, it is possible to extend the life span of the dicing blade by preventing clogging or damage to the blade and by evenly dividing the load on both edges of the dicing blade.

In addition, in the embodiment illustrated in FIG. 108, p-side terminal 23 and n-side terminal 24, posted on edge e1, and p-side terminal 23 and n-side terminal 24, posted on edge e2, are alternately arranged in the extending direction of dicing area d2 but in other embodiments are arranged in other configurations. Specifically, in some embodiments, as long as portions of p-side terminal 23 and n-side terminal 24 are not arranged with being biased to edge e1 or edge e2, the positioning of p-side terminal 23 and n-side terminal 24 is adequate.

Then, the interval between p-side terminal 23 and n-side terminal 24 that separates terminal surfaces 23a and 24a exposed on side 25b of sealing part 25 is selected to avoid a short-circuit due to poor placement of connection materials 104a and 104b.

The next step is to remove resist mask 42, for example, by using organic solvent in the wet ashing technique, or oxygen plasma in the dry ashing technique.

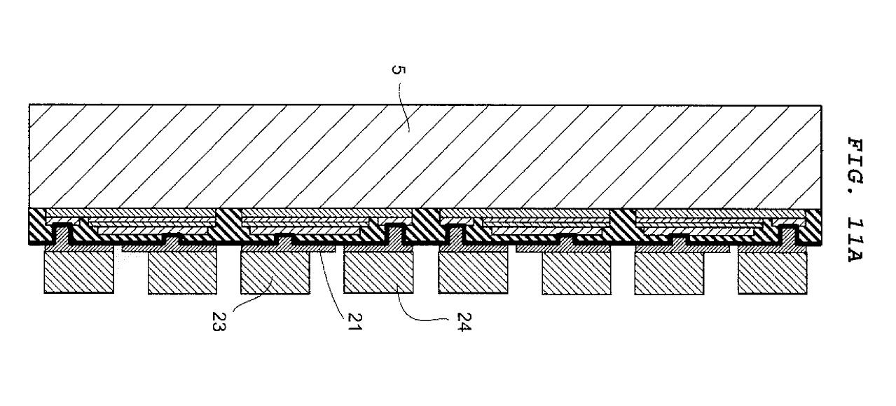

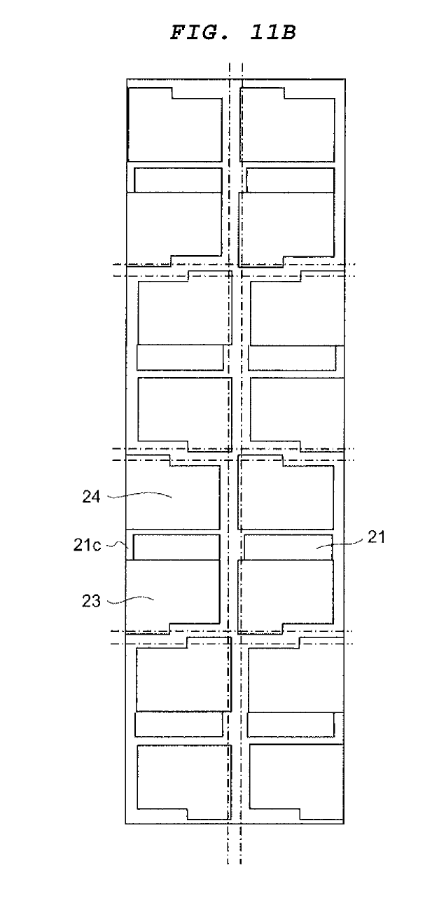

FIG. 11A and the plan view thereof, FIG. 112, represent conditions after resist mask 42 is removed.

As shown in FIG. 11A, p-side terminal 23 is formed in a smaller size than p-side interconnect 21. As a result, as shown in FIG. 112, except for the notched part 21c, p-side interconnect 21 is formed in such a way that it extends from p-side terminal 23 to n-side terminal 24.

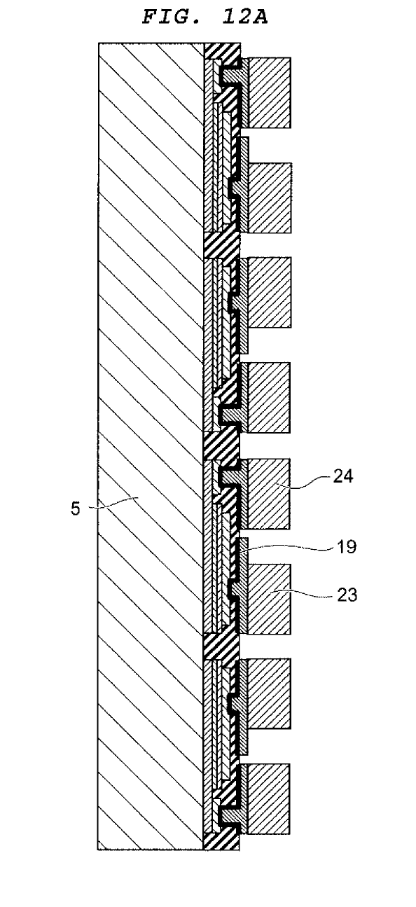

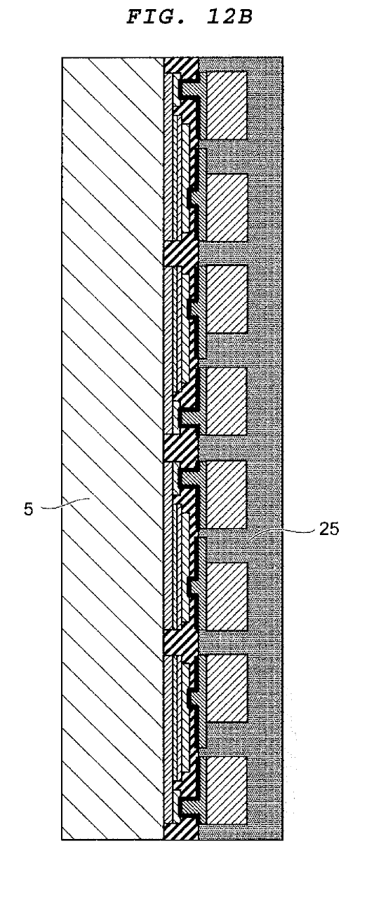

The next step, as shown in FIG. 12A, is using p-side terminal 23, n-side terminal 24, and a part of p-side interconnect 21 extended from p-side terminal 23 as masks in the wet etching technique to remove the exposed part of metal seed 19. As a result, the interval between p-side interconnect 21 and n-side interconnect 22 is electrically divided.

Next, as shown in FIG. 122, p-side terminal 23, n-side terminal 24 and sealing part 25, which covers the surface of insulation 18 exposed therebetween, are formed. In sealing part 25, it is possible to include, for example, carbon black, in order to give opacity to the emission of light-emitting layer 13. Also, it is possible to include a powder such as titanium oxide, which reflects the emission of light-emitting layer 13.

The next step, as shown in FIG. 13A, is to remove substrate 5. Substrate 5 is removed, for example, by the laser lift-off technique. For example, a laser beam is radiated to n-type GaN layer 11 from the main surface of the opposite side of the laminated body 15 that is a back side. The laser beam has a wavelength absorbed on n-type GaN layer 11 and has transparency for the substrate 5. Then, on the interface of substrate 5 and n-type GaN layer 11, n-type GaN layer 11 absorbs the energy of the laser beam in order to decompose gallium (Ga) or nitrogen (N). As a result of this decomposition reaction, substrate 5 and n-type GaN layer 11 are separated.

In addition, through this substrate 5, a laser beam is radiated and divided several times in order to be directed to individual areas. As a result, substrate 5 is removed from the first main surface 15a of the laminated body 15; it is then possible to improve the light extraction efficiency.

Laminated body 15, which is separated from substrate 5, is supported by sealing part 25 provided on the second main surface 15b. More precisely, a Cu film, which is the structure of n-side terminal 24 and p-side terminal 23, is formed to be thick enough to fill the interval between p-side terminal 23 and n-side terminal 24 on sealing part 25. As a result, it is possible to ensure the mechanical strength of a wafer when separated from substrate 5.

In addition, for sealing part 25, and each interconnect element, the metal that constitutes the terminal is flexible compared to the substrate 5. That is why, in the process of crystal growth, the stress that inherent in laminated body 15 is absorbed by sealing part 25 during the peeling of substrate 5. As a result, it is possible to avoid the crystal destruction caused by the formation of cracks in laminated body 15.

The next step is to wash the first main surface 15a of laminated body 15, from which the substrate has been removed. For example, residual gallium (Ga) is removed from the first main surface 15 with hydrochloric acid.

In addition, for example, the first main surface 15a is etched with potassium hydroxide (KOH) water solution or tetra methyl ammonium hydroxide (TMAH). As a result, as shown in FIG. 13B, the irregularities caused by the differences in etching speed due to a crystal plane orientation are formed on the first main surface 15a. Or, according to the patterning, which uses a resist mask, on the first main surface 15a, it is possible to form the irregularities. Because of the irregularities formed on the first main surface 15a, it is possible to improve the light extraction efficiency.

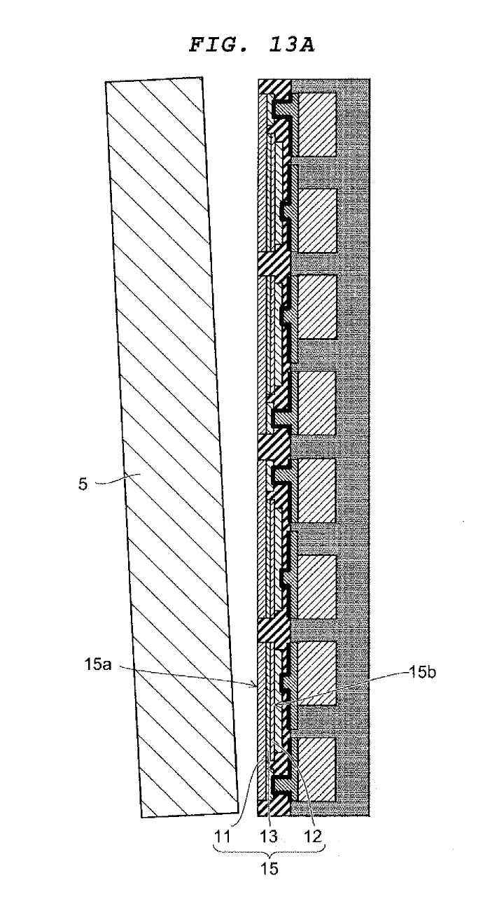

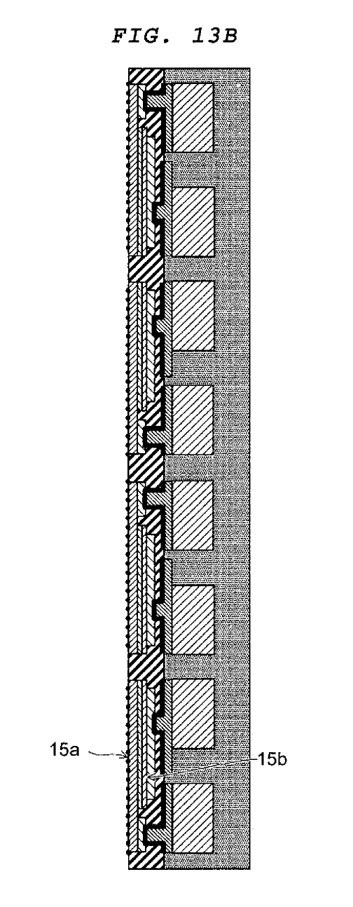

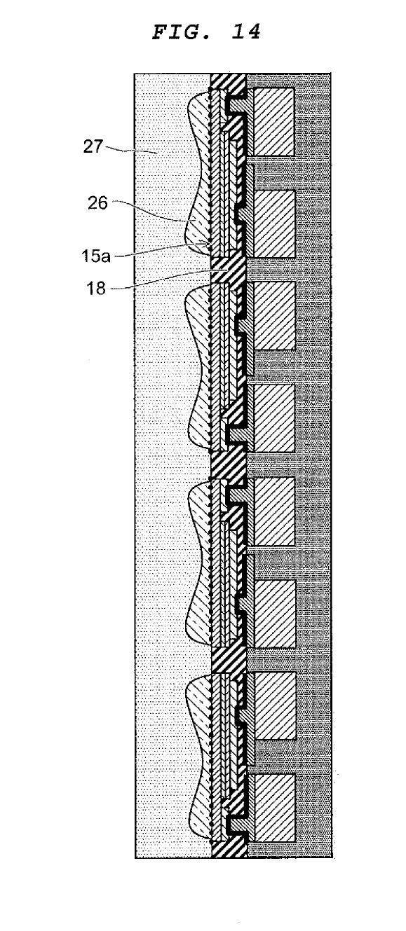

The next step, as shown in FIG. 14, is to form light-transmitting part 27 on top of the first main surface 15a and on the top of insulation 18, which is exposed between adjacent laminated bodies 15. The light-transmitting part 27 is formed by thermosetting after, for example, phosphor particle are supplied by processes such as printing, potting, molding, or compression molding to liquid transparent resin in which fluorescence substance particles are dispersed. In transparent resin, materials that have transparency to light emitted from light-emitting layer 13 or phosphor are used; for example, silicone resin, acrylic resin, or liquid glass.

In this case, between the first main surface 15a and light-transmitting part 27, it is possible to form lens 26; in lens 26 it is possible to use the materials that have transparency to light emitted from light-emitting layer 13, such as silicone resin, acrylic resin, glass, etc. Lens 26 can be formed, for example, by etching technique using a gray scale mask, or by imprinting technique.

In alternative embodiments, no lens 26 is formed between the first main surface 15a and light-transmitting part 27.

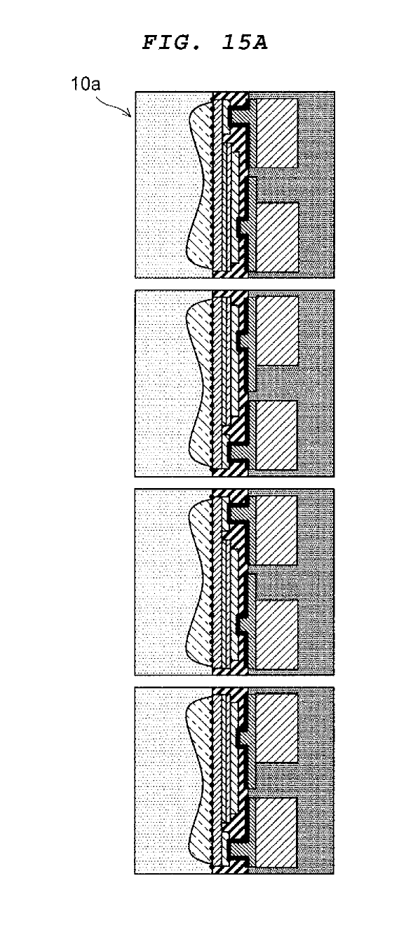

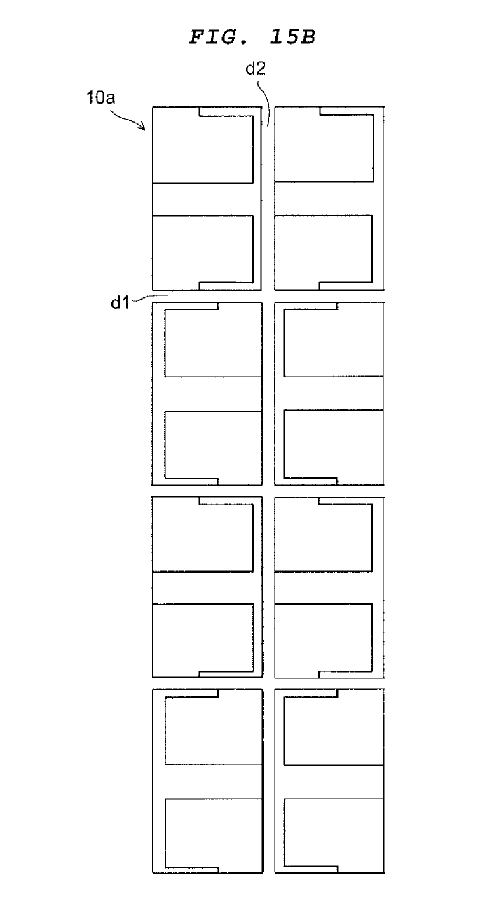

Now, as shown in FIGS. 15A and 15B, at the position of dicing region d1 and d2 formed on the lattice, light-transmitting part 27, insulation 18, and sealing part 25 are cut, and multiple semiconductor light-emitting devices 10a are separated into individual pieces. Light-transmitting part 27, insulation 18, and sealing part 25, for example, can be cut by using a dicing blade or by laser radiation.

In this case, on dicing regions d1 and d2, the part that extends beyond the width (edge e1, edge e2, edge e3, and edge e4) of the dicing blade of p-side terminal 23 and n-side terminal 24 are cut. As a result, on the side of sealing part 25, terminal surfaces 23a, 23b, 24a, and 24b are exposed.

In the same way, on p-side interconnect 21 and n-side interconnect 22, the portion that extends into dicing region d1 and d2 is also cut. As a result, on the sides of sealing part 25, the sides 21a and 21b of p-side interconnect 21 and the sides 22a and 22b of n-side interconnect 22 are exposed. (refer to FIG. 1A).

At the time of the dicing process, substrate 5 has already been removed. In addition, when dicing regions d1 and d2, because laminated body 15 does not exist, it is possible to avoid damage to laminated body 15. Also, in the semiconductor light-emitting device 10a that is separated into individual pieces, the edges of laminated body 15 can be a protected structure covered by insulation 18.

It is noted that, in the semiconductor light-emitting device 10a that is separated into individual pieces, both a single-chip structure, which has only one laminated body 15, and a multichip structure, which has several laminated bodies 15, are possible.

When semiconductor light-emitting devices 10a have been be separated into individual pieces, terminal surfaces used for connecting to substrate are completed exposed and the remaining parts are covered by resin or other protective layers. As a result, each individual semiconductor light-emitting device 10a does not need wiring or packaging. This can be a big reduction of production cost. More precisely, the semiconductor light-emitting device 10a is separated into individual pieces that already have wiring and packaging incorporated. As a result, it is possible to increase productivity and, furthermore, it is easy to reduce costs.

### (Manufacturing Method of Light-Emitting Module)

Now we will illustrate the manufacturing method of light-emitting module 201a.

In addition, each figure A is a schematic plan view illustrating the manufacturing method, and each figure B is an A-A sectional view of A.

As shown in FIGS. 16A and 16B, on the surface of base 101 of substrate 100, electrodes 102a and 102b are formed. The part of the semiconductor light-emitting device that is electrically connected to electrodes 102a and 102b is exposed from insulation part 103.

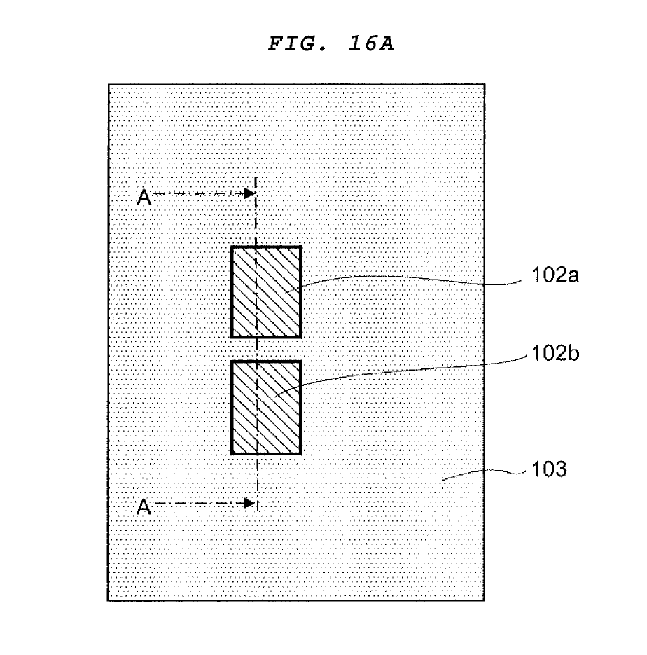

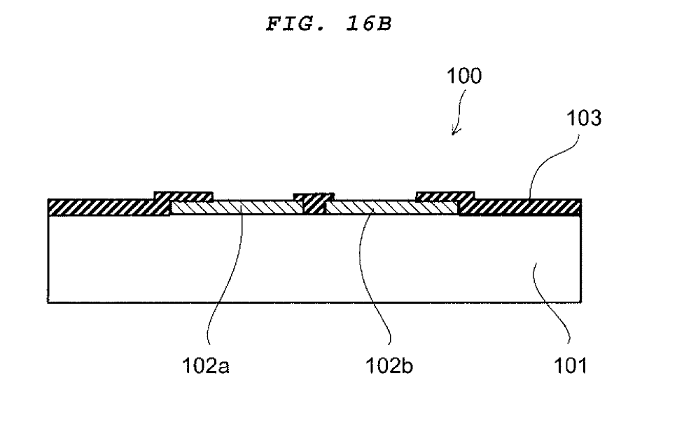

In the next step, as shown in FIGS. 17A and 17B, connecting material 104a is formed on a surface of electrode 102a and connecting material 104b is formed on a surface of electrode 102b. For example, on electrodes 102a and 102b, it is possible to form connecting materials 104a and 104b while applying the solder through a screen printing technique that uses a metal mask.

Then, as shown in FIGS. 18A and 18B, the die bonding technique is used to install the semiconductor light-emitting device 10a on the substrate 100. During die bonding, terminal surface 23a and connecting material 104a face each other, and terminal surface 23b and connecting material 104b face each other. In this condition, connecting materials 104a and 104b are melted and then solidified. As a result, terminal surface 23a and 23b are connected to electrode 102a through connecting material 104a, and terminal surfaces 24a and 24b are connected to electrode 102b through connecting material 104b.

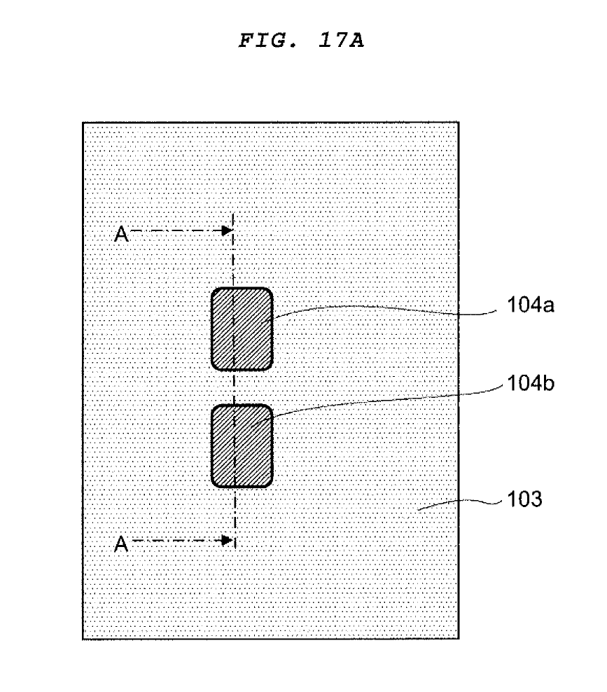

This is how, as shown in FIGS. 19A and 19B, light-emitting module 201a is manufactured.

### Embodiment 2

### The Semiconductor Light-Emitting Device)

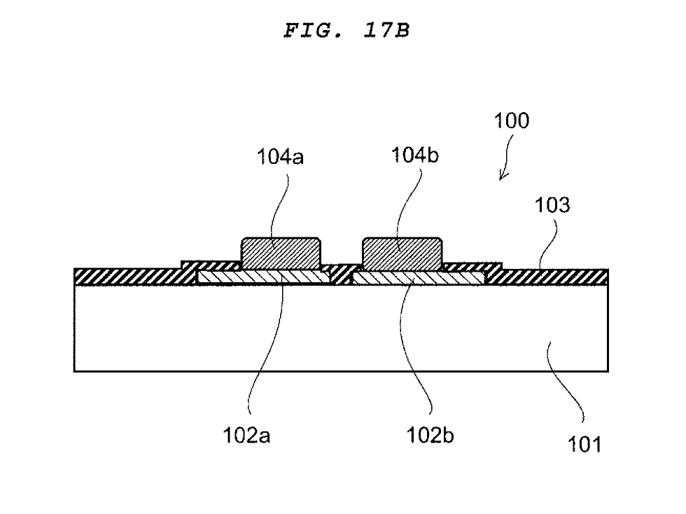

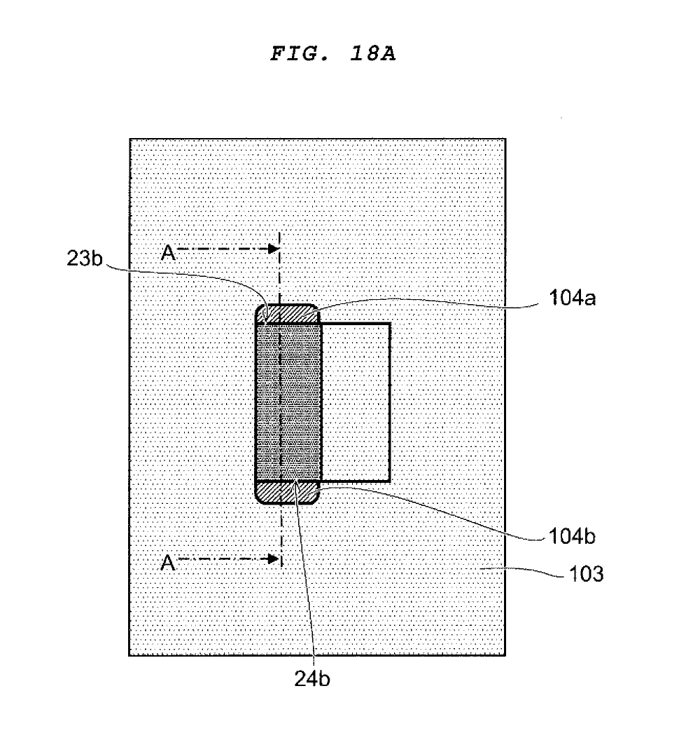

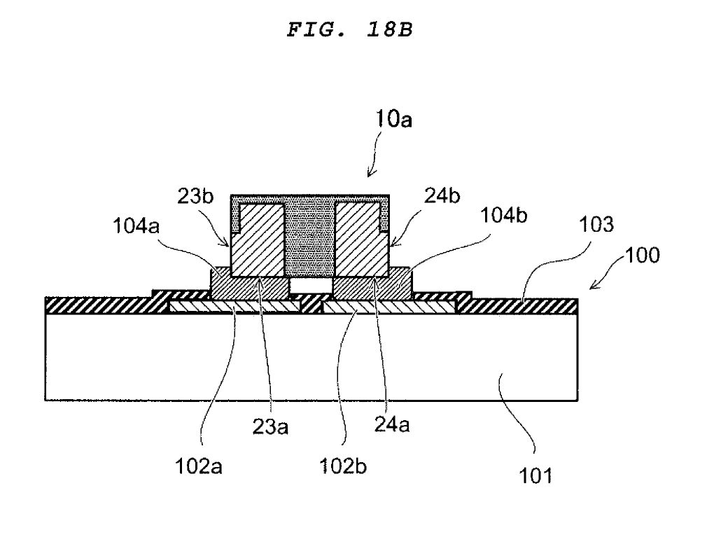

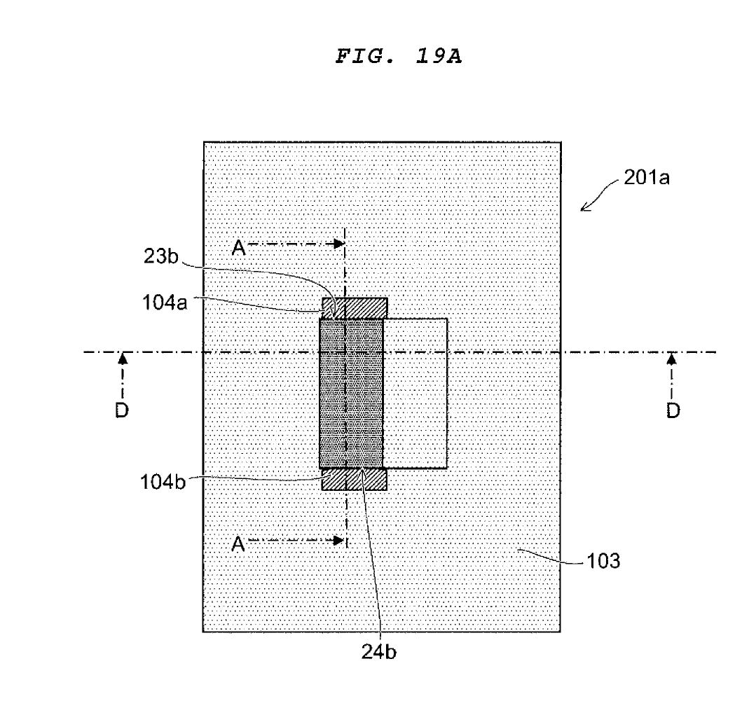

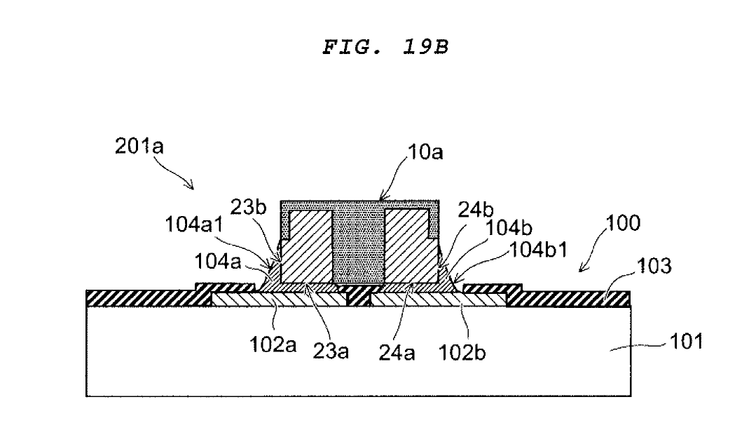

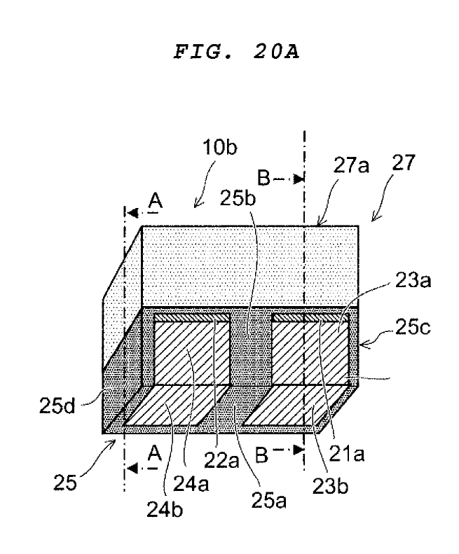

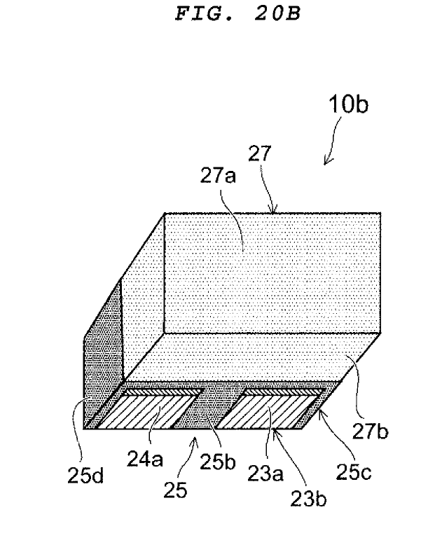

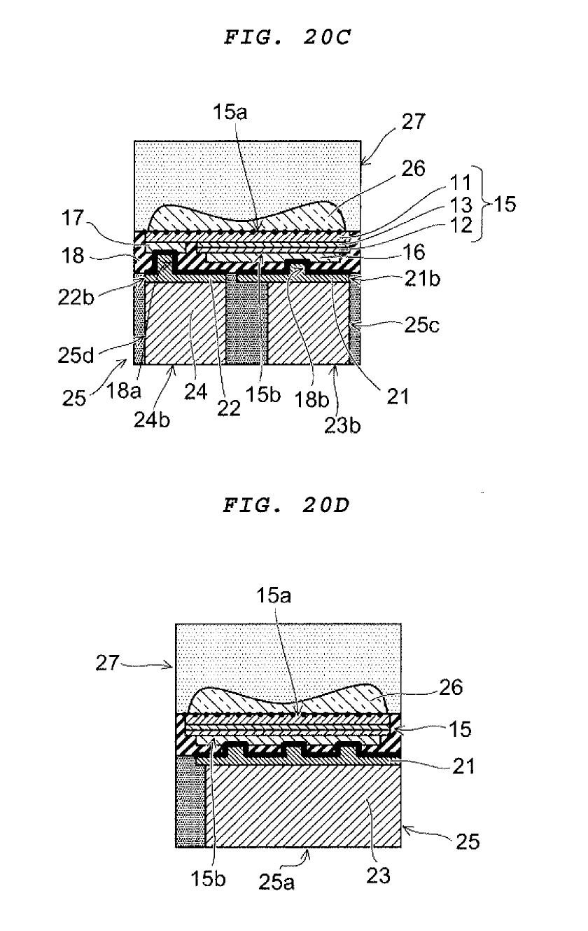

FIGS. 20A to 20D are schematic diagrams that illustrate a semiconductor light-emitting device according to a second embodiment.

FIGS. 20A and 20B are perspective views that illustrate the semiconductor light-emitting device 10b of the second embodiment.

FIG. 20C is an A-A sectional view of FIG. 20A, and FIG. 20D is a B-B sectional view of FIG. 20A.

As shown in FIGS. 20A to 20C, the outer sides of the semiconductor light-emitting device 10b form a quadrangular prism shape, and semiconductor light-emitting device 10b includes sealing part 25 and light-transmitting part 27.

In the case of the semiconductor light-emitting device 10a, which is illustrated by FIGS. 1A to 1D, terminal surface 23b is exposed on side 25c, and terminal surface 24b is exposed on side 25d.

According to this, in the case of the semiconductor light-emitting device 10b, terminal sides 23b and 24b are exposed on side 25a. More precisely, for the semiconductor light-emitting device 10b, the side on which terminal 23b and 24b are exposed is different from the side on which the semiconductor light-emitting device 10a is exposed.

When connecting the semiconductor light-emitting device 10b to substrate 100, connecting material 104a is not only applied to terminal surface 23a, but also contacts and forms an electrical connection with terminal surface 23b. Similarly, connecting material 104b is not only applied to terminal surface 24a, but also and forms an electrical connection with terminal surface 24b. In this case, fillets 104a1 and 104b1 are formed at a different location, but this yields similar results to those of the previously described semiconductor light-emitting device 10a.

It is possible to use the same kind of manufacturing method as used for the semiconductor light-emitting device 10a to manufacture the semiconductor light-emitting device 10b. More precisely, it is possible to use the same kind of processing method as the previously described semiconductor light-emitting device 10a, except when exposing terminal surfaces 23b and 24b from the side 25a, when using a dicing blade or laser radiation to cut the sides.

### (Light-Emitting Module)

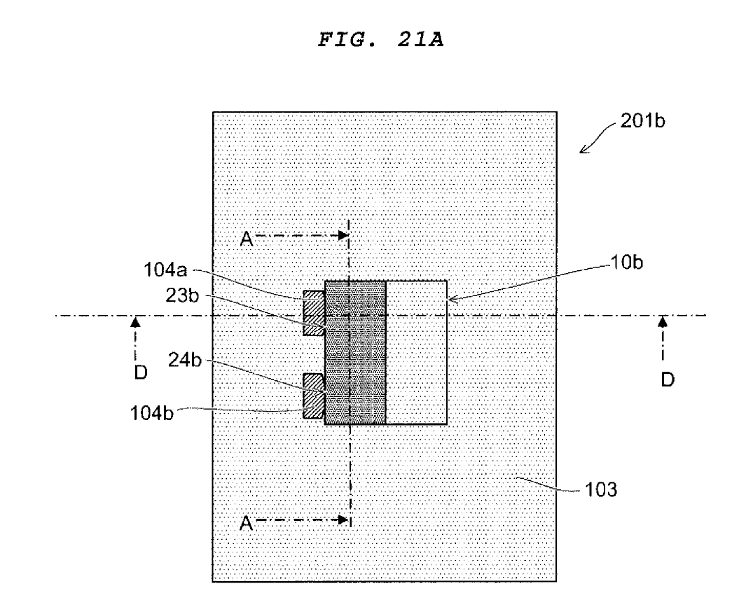

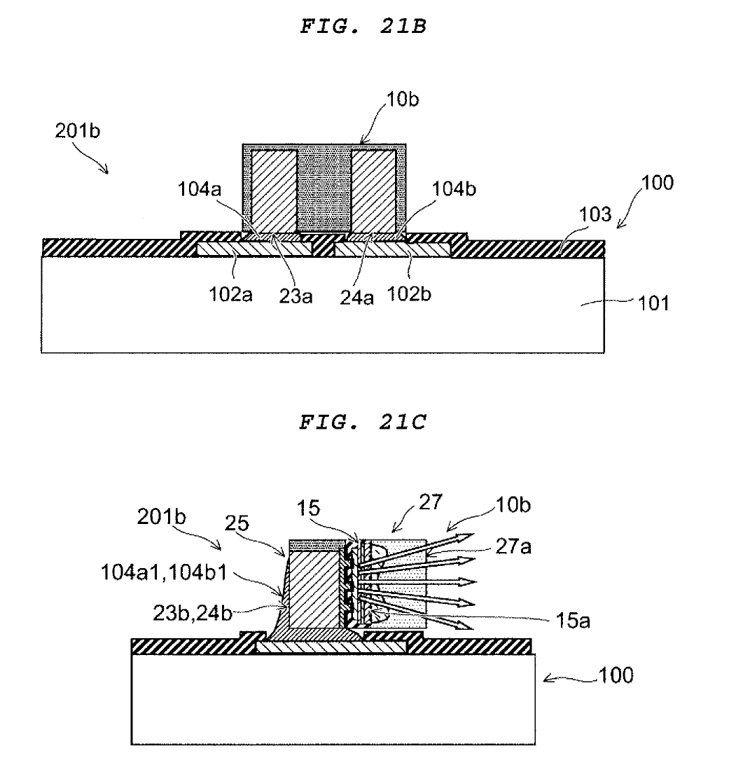

FIGS. 21A to 21C are schematic diagrams that illustrate the light-emitting module 201b of the semiconductor light-emitting device 10b.

FIG. 21A is a schematic plain view of the light-emitting module 201b; FIG. 21B is an A-A sectional view of FIG. 21A; and FIG. 21C is a D-D sectional view of FIG. 21A.

As shown in FIGS. 21A to 21C, the light-emitting module 201b includes the semiconductor light-emitting device 10b and the substrate 100.

As previously described, for the semiconductor light-emitting device 10b, terminal surfaces 23b and 24b are formed on different sides than on the semiconductor light-emitting device 10a. That is why, for the light-emitting module 201b, the location at which fillets 104a1 and 104b1 are formed is different than for light-emitting module 201a.

However, even though the place where fillets 104a1 and 104b1 are formed is different from the previously described light-emitting module 201a, the same kind of results can be obtained. The manufacturing method of the light-emitting module 201b can be similar to the manufacturing method of the light-emitting module 201a. Consequently, details of the manufacturing method of the light-emitting module 201b that are common with the manufacturing method of the light-emitting module 201a are omitted.

### Embodiment 3

### The Semiconductor Light-Emitting Device

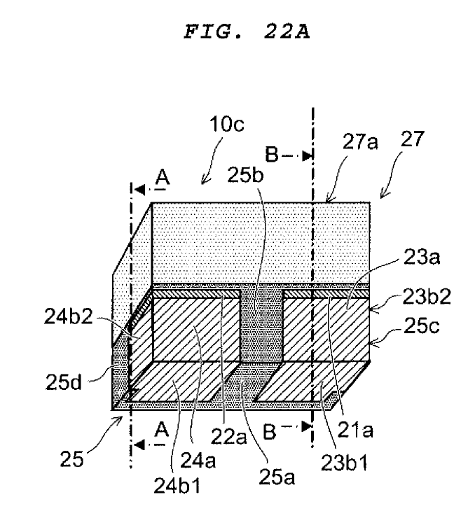

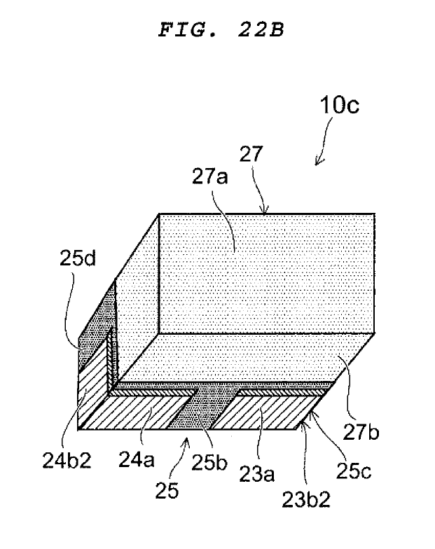

FIGS. 22A to 22D are schematic diagrams that illustrate a semiconductor light-emitting device according to a third embodiment.

FIGS. 22A and 22B are schematic perspective views of the semiconductor light-emitting device 10c of the third embodiment; FIG. 22C is an A-A sectional view of FIG. 22A; and FIG. 22D is a B-B sectional view of FIG. 22A.

As shown in FIGS. 22A to 22C, the outer sides of the semiconductor light-emitting device 10c form a quadrangular prism shape. The semiconductor light-emitting device 10c includes sealing part 25 and light-transmitting part 27.

In the case of the semiconductor light-emitting device 10c, terminal surface 23b1 (which represents an example of the second terminal surface) and terminal surface 24b1 (which represents an example of the fourth terminal surface) are exposed on the side 25a. Then, terminal surface 23b2 (which represents an example of the second terminal surface) is exposed on the side 25c, while the terminal surface 24b2 (which represents an example of the fourth terminal surface) is exposed on the side 25d. More precisely, the semiconductor light-emitting device 10c has the same sides where terminal surfaces 23b2 and 24b2 are exposed as does the semiconductor light-emitting device 10a, and has the same sides where terminal surfaces 23b1 and 24b1 are exposed as does the semiconductor light-emitting device 10b. In this case, fillets 104a1 and 104b1 are formed in a position for the semiconductor light-emitting device 10a, and are formed in another position for the semiconductor light-emitting device 10b; but, as previously described, the semiconductor light-emitting device 10a or 10b can yield the same results.

It is possible to use the same kind of manufacturing method of the semiconductor light-emitting device 10a to manufacture the semiconductor light-emitting device 10c. More precisely, it is possible to use the same kind of processing method as with the previously described semiconductor light-emitting device 10a, except when using a dicing blade or laser radiation to cut the sides, when exposing terminal surfaces 23b and 24b from the side 25a, when exposing terminal surface 23b2 from side 25c, and when exposing 24b2 from side 25d. The details about manufacturing the semiconductor light-emitting device 10c have been previously described in conjunction with other embodiments and are omitted as well.

### (Light-Emitting Module)

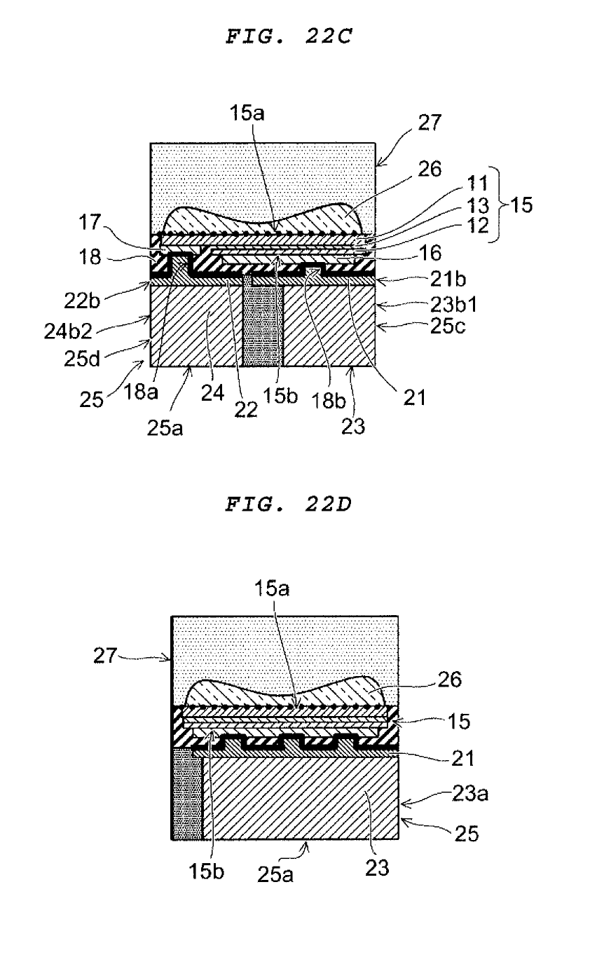

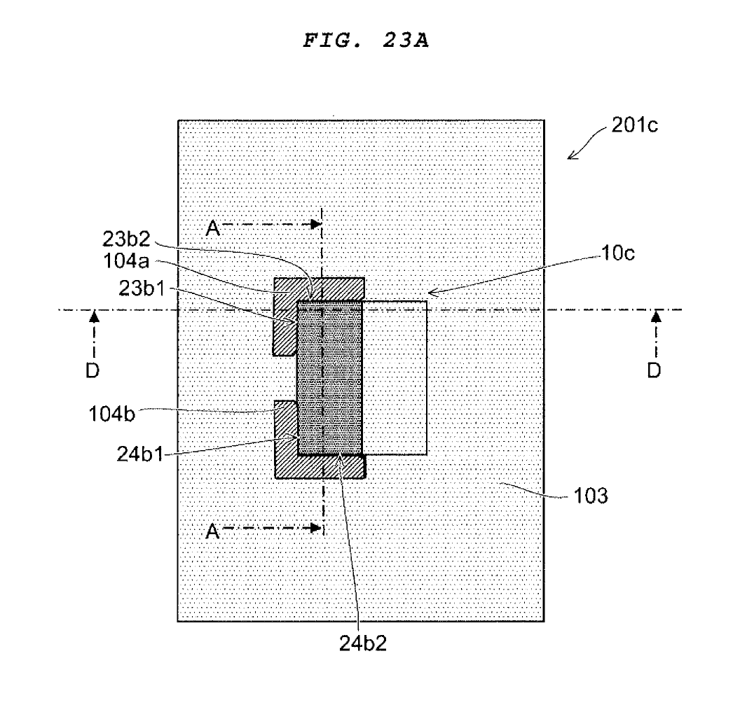

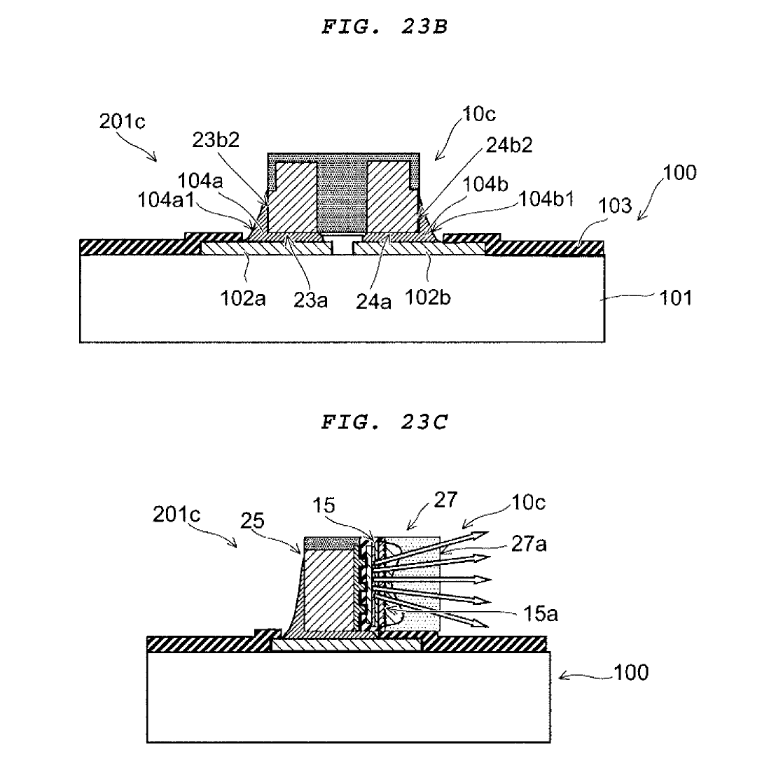

FIGS. 23A to 23C are schematic diagrams that illustrate the light-emitting module 201c of the semiconductor light-emitting device 10c.

FIG. 23A is a schematic plain view of the light-emitting module 201c; FIG. 23S is an A-A sectional view of FIG. 23A; and FIG. 23C is a D-D sectional view of FIG. 23A.

As shown in FIGS. 23A to 23C, the light-emitting module 201c is provided by the semiconductor light-emitting device 10c and the substrate 100.

As previously described, for the semiconductor light-emitting device 10c, the side on which terminal surfaces 23b1, 23b2, 24b1, and 24b2 are exposed is different from the side of the semiconductor light-emitting device 10a. That is why, for the light-emitting module 201c, the location where fillets 104a1 and 104b1 are formed is different from the one of the light-emitting module 201a.

However, even though the place where fillets 104a1 and 104b1 are formed is different, as with the previously described light-emitting module 201a, the same kind of results can be obtained. The manufacturing method of the light-emitting module 201c can be similar to the manufacturing method of the light-emitting module 201a. Consequently, details of the manufacturing method of the light-emitting module 201c common to other embodiments are omitted.

In addition, according to the previously described manufacturing method of the semiconductor light-emitting device, leaving the substrate 5 increases mechanical strength and improves the reliability of the semiconductor light-emitting device and light-emitting module.

Also, it is possible to fill sealing part 25 inside the opening side provided by dicing region d1.

For example, when insulation 18 is formed from the polyimide, as polyimide is light-transmissive, there is a possibility that the light will leak from the edges of insulation 18. If we try to fill sealing part 25 inside the opening side provided by dicing region d1, it is preferable to cover insulation 18 by cover sealing part 25, which has a light-blocking effect; because insulation can cover the edges, it is possible to inhibit the leaking of light from the edges of insulation 18.

Also, it is possible to extend p-side interconnect and n-side interconnect on dicing area d2 without going beyond the edges e1 and e2. In this case, only portions of terminals can extend into dicing area d2 and can go beyond the edges e1 and e2.

According to embodiments of the invention, we have illustrated a semiconductor light-emitting device, a light-emitting module, and a manufacturing method of the semiconductor light-emitting device, all of which facilitate the improvement of manufacturability and miniaturization.

Above, a few embodiments of this invention have been illustrated; these embodiments are presented as examples and are not intended to limit the scope of the embodiment. These new embodiments can be implemented in various forms, and there can be various omissions, replacements, or changes without deviating from the scope of the embodiment. These embodiments include the scope of the embodiment and its equivalent, and the patent claims along with the summary and various deformation cases. In addition, each of the embodiments described above can be carried out in combination with each other.

While certain embodiments have been described, these embodiments have been presented by way of example only and are not intended to limit the scope of the embodiments. Indeed, the novel embodiments described herein may be embodied in a variety of other forms; furthermore, various omissions, substitutions, and changes in the form of the embodiments described herein may be made without departing from the spirit of the embodiments. The accompanying claims and their equivalents are intended to cover such forms or modifications as would fall within the scope and spirit of the embodiments.

What is claimed is:

1. A semiconductor light-emitting device comprising:
a laminated body that comprises a first semiconductor layer of a first conductivity type, a second semiconductor layer of a second conductivity type and a light-emitting layer between the first semiconductor layer and the second semiconductor layer, and is configured to emit light from the light-emitting layer through a first main surface of the laminated body;
a first electrode, which is connected to the first semiconductor layer on a second main surface of the laminated body, which is opposite to the first main surface of the laminated body;
a second electrode, which is connected to the second semiconductor layer on the second main surface of the laminated body;
a first terminal, which is connected to the first electrode;
a second terminal, which is connected to the second electrode; and
a sealing part which covers the first and the second terminals, which are formed on the second main surface of the laminated body, wherein
the first terminal includes a first terminal surface, which is exposed on a first side of the sealing part that intersects the first main surface, and a second terminal surface, which is exposed on a second side of the sealing part that intersects the first side,
the second terminal includes a third terminal surface which is exposed on the first side, and a fourth terminal surface which is exposed to at least one of the second side and a third side of the sealing part, which is parallel to the second side,
the first and the second terminal surfaces are continuously provided, and
the third and the fourth terminal surfaces are continuously provided.

2. The semiconductor light-emitting device according to claim 1, wherein
the first, the second, the third, and the fourth terminal surfaces are provided on each exposed side.

3. The semiconductor light-emitting device according to claim 1, wherein
the sealing part has a quadratic prism shape.

4. The semiconductor light-emitting device according to claim 1, further comprising:
a first interconnect, which is connected to the first electrode, the first terminal formed on the first interconnect;
a second interconnect, which is connected to the second electrode, the second terminal formed on the second interconnect; and
a notched part, which is formed on a corner of the first side of the sealing part between the first interconnect and the second interconnect.

5. A light-emitting module comprising:
a semiconductor light-emitting device comprising
a laminated body that comprises a first semiconductor layer of a first conductivity type, a second semiconductor layer of a second conductivity type and a light-emitting layer between the first semiconductor layer and the second semiconductor layer, and is configured to emit light from the light-emitting layer through a first main surface of the laminated body;
a first electrode, which is connected to the first semiconductor layer on a second main surface of the laminated body, which is opposite to the first main surface of the laminated body;
a second electrode, which is connected to the second semiconductor layer on the second main surface of the laminated body;
a first terminal, which is connected to the first electrode;
a second terminal, which is connected to the second electrode; and
a sealing part which covers the first and the second terminals, which are formed on the second main surface of the laminated body, wherein
the first terminal includes a first terminal surface, which is exposed on a first side of the sealing part that intersects the first main surface, and a second terminal surface, which is exposed on a second side of the sealing part that intersects the first side,
the second terminal includes a third terminal surface which is exposed on the first side, and a fourth terminal surface which is exposed to at least one of the second side and a third side of the sealing part, which is parallel to the second side,
the first and the second terminal surfaces are continuously provided, and
the third and the fourth terminal surfaces are continuously provided;
a substrate including third and fourth electrodes, wherein
the third electrode is connected to the first and second terminal surfaces of the semiconductor light-emitting device, and
the fourth electrode is connected to the third and fourth terminal surfaces of the semiconductor light-emitting device.

6. The light-emitting module according to claim 5, wherein
the first, the second, the third, and the fourth terminal surfaces are provided on each exposed side.

7. The light-emitting module according to claim 5, wherein
the sealing part has a quadratic prism shape.

8. The light-emitting module according to claim 5, wherein the semiconductor light-emitting device further comprises:
a first interconnect, which is connected to the first electrode, the first terminal formed on the first interconnect;
a second interconnect, which is connected to the second electrode, the second terminal formed on the second interconnect; and
a notched part, which is formed on a corner of the first side of the sealing part between the first interconnect and the second interconnect.

9. A method for manufacturing a semiconductor light-emitting device comprising a first semiconductor layer of a first conductivity type, a second semiconductor layer of a second conductivity type, and a light-emitting layer formed between the first and second semiconductor layers,
the method comprising the steps of:
forming a laminated body that includes the first semiconductor layer, the second semiconductor layer, and the light-emitting layer and is configured to emit light from the light-emitting layer through a first main surface of the laminated body;
forming on a second main surface of the laminated body which is the opposite to the first main surface of the laminated body, a first terminal which is connected to the first semiconductor layer through a first electrode and a second terminal which is connected to the second semiconductor layer through a second electrode;
forming a sealing part which covers the first and second terminals; and
separating the laminated body into pieces,
wherein the step of separating the laminated body into pieces comprises the steps of:
exposing a first terminal surface of the first terminal on a first side of the sealing part that intersects the first main surface;
exposing a second terminal surface of the first terminal on a second side of the sealing part that intersects the first side;
exposing a third terminal surface of the second terminal on the first side;
exposing a fourth terminal surface of the second terminal on at least one of the second side and a third side of the sealing part which is parallel to the second side;
making the first and the second terminal surfaces to be continuous; and
making the third and the fourth terminal surfaces to be continuous.

10. The method for manufacturing a semiconductor light-emitting device according to claim 9, wherein
the first, the second, the third, and the fourth terminal surfaces are provided on each exposed side.
